(19) United States
(12) Patent Application Publication
(10) Pub. No.: US 2024/0186256 A1
(43) Pub. Date: Jun. 6, 2024

(54) SEMICONDUCTOR DEVICE

(71) Applicant: ROHM CO., LTD., Kyoto-shi (JP)

(72) Inventors: Hiroto SAKAI, Kyoto-shi (JP); Yuta OKAWAUCHI, Kyoto-shi (JP)

(21) Appl. No.: 18/440,470

(22) Filed: Feb. 13, 2024

Related U.S. Application Data
(63) Continuation of application No. PCT/JP2022/032604, filed on Aug. 30, 2022.

(30) Foreign Application Priority Data
Sep. 29, 2021 (JP) 2021-159368

(51) Int. Cl. H01L 23/538; H01L 23/00; H01L 25/07

(52) U.S. Cl. CPC H01L 23/5386; H01L 24/32; H01L 24/48; H01L 24/73; H01L 25/072; H01L 2224/32225; H01L 2224/48227; H01L 2224/73265

(57) ABSTRACT

A semiconductor device includes two first semiconductor elements, a first conductor, and a first power terminal. Each of the two semiconductor elements includes a first electrode, a second electrode, and a third electrode and is controlled to switch between an on-state and an off-state by a first drive signal inputted to the third electrode. The first conductor is electrically interposed between the first electrodes of the two first semiconductor elements. The first power terminal is electrically connected to the first conductor and electrically conducting to the first electrodes of the two first semiconductor elements. The two first semiconductor elements are electrically connected in parallel. The first conductor is disposed to avoid being located on a portion of a first line segment connecting centers of the two first semiconductor elements as viewed in a thickness direction of the first conductor.

### TECHNICAL FIELD

The present disclosure relates to a semiconductor device.

### BACKGROUND ART

Conventionally, semiconductor devices including power semiconductor elements, such as metal-oxide-semiconductor field-effect transistors (MOSFETs) and insulated gate bipolar transistors (IGBTs), have been known. For such a semiconductor device, paralleling a plurality of power semiconductor elements is known to ensure the current carrying capacity of the device (e.g., JP-A-2016-225493). The semiconductor device (power module) disclosed in JP-A-2016-225493 includes a plurality of first semiconductor elements, a plurality of first connecting wirings, a wiring layer, and a signal terminal. The first semiconductor elements are MOSFETs, for example. Each first semiconductor element turns on and off in response to a drive signal inputted to the gate terminal. The first semiconductor elements are connected in parallel. The first connecting wirings, which may be wires, connect the gate terminals of the first semiconductor elements and the wiring layer. The wiring layer is connected to the signal terminal. The signal terminal is connected to the gate terminals of the first semiconductor elements via the wiring layer and the first connecting wirings. The signal terminal is used to provide a drive signal to the gate terminals of the first semiconductor elements for driving the first semiconductor elements.

### BRIEF DESCRIPTION OF THE DRAWINGS

FIG. 1 is a perspective view of a semiconductor device according to a first embodiment.

FIG. 2 is a plan view of the semiconductor device of the first embodiment, with the sealing member indicated by an imaginary line.

FIG. 3 is a plan view corresponding to FIG. 2, omitting the connecting members and the sealing member.

FIG. 4 is a sectional view taken along line IV-IV in FIG. 2.

FIG. 5 is a sectional view taken along line V-V in FIG. 2.

FIG. 6 is a sectional view taken along line VI-VI in FIG. 2.

FIG. 7 is a plan view corresponding to FIG. 3, showing relevant portions of a semiconductor device according to a first variation of the first embodiment.

FIG. 8 is a plan view corresponding to FIG. 3, showing relevant portions of a semiconductor device according to a second variation of the first embodiment.

FIG. 9 is a plan view corresponding to FIG. 3, showing relevant portions of a semiconductor device according to a third variation of the first embodiment.

FIG. 10 is a plan view corresponding to FIG. 3, showing relevant portions of a semiconductor device according to a fourth variation of the first embodiment.

FIG. 11 is a plan view corresponding to FIG. 3, showing relevant portions of a semiconductor device according to another variation of the first embodiment.

FIG. 12 is a perspective view of a semiconductor device according to a second embodiment.

FIG. 13 is a perspective view corresponding to FIG. 12, omitting the sealing member.

FIG. 14 is a plan view of the semiconductor device of the second embodiment, with the sealing member indicated by an imaginary line.

FIG. 15 is a perspective view corresponding to FIG. 14, omitting some of the connecting members.

FIG. 16 is a plan view corresponding to FIG. 15, omitting some components.

FIG. 17 is a sectional view taken along line XVII-XVII in FIG. 14.

FIG. 18 is a plan view corresponding to FIG. 16, showing relevant portions of a semiconductor device according to a first variation of the second embodiment.

FIG. 19 is a plan view corresponding to FIG. 16, showing relevant portions of a semiconductor device according to a second variation of the second embodiment.

FIG. 20 is a plan view corresponding to FIG. 16, showing relevant portions of a semiconductor device according to a third variation of the second embodiment.

FIG. 21 is a plan view corresponding to FIG. 16, showing relevant portions of a semiconductor device according to a fourth variation of the second embodiment.

FIG. 22 is a perspective view of a semiconductor device according to a third embodiment.

FIG. 23 is a perspective view corresponding to FIG. 22, omitting a portion of the case (top plate) and the sealing member.

FIG. 24 is a plan view of the semiconductor device according to the third embodiment.

FIG. 25 is a plan view corresponding to FIG. 24, omitting a portion of the case (top plate) and the sealing member.

FIG. 26 is an enlarged plan view showing relevant portions of FIG. 25, omitting the connecting members.

FIG. 27 is an enlarged plan view showing relevant portions of FIG. 25, omitting the connecting members.

FIG. 28 is a sectional view taken along line XXVIII-XXVIII in FIG. 25.

FIG. 29 is a sectional view taken along line XXIX-XXIX in FIG. 25.

FIG. 30 is a sectional view taken along line XXX-XXX in FIG. 25.

FIG. 31 is a sectional view taken along line XXXI-XXXI in FIG. 25.

FIG. 32 is a sectional view taken along line XXXII-XXXII in FIG. 25.

### DETAILED DESCRIPTION OF EMBODIMENTS

Hereinafter, preferred embodiments of the present disclosure will be described with reference to the drawings. In the description below, the same or similar components are given the same reference numerals, and overlapping explanations are omitted. In the present disclosure, the terms “first”, “second”, “third”, and so on are used merely as labels and not intended to limit the order of the objects modified by these terms.

In the description of the present disclosure, the expression “An object A is formed in an object B”, and “An object A is formed on (or over) an object B” imply the situation where, unless otherwise specifically noted, “the object A is formed directly in or on the object B”, and “the object A is formed on or over the object B, with something else interposed between the object A and the object B”. Likewise, the expression “An object A is disposed in an object B”, and “An object A is disposed on (or over) an object B” imply the situation where, unless otherwise specifically noted, “the object A is disposed directly in or on the object B”, and “the object A is disposed on or over the object B, with something else interposed between the object A and the object B”. Further, the expression “An object A is located on (or over) an object B” implies the situation where, unless otherwise specifically noted, “the object A is located on (or over) the object B, in contact with the object B”, and “the object A is located on (or over) the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”.

### First Embodiment

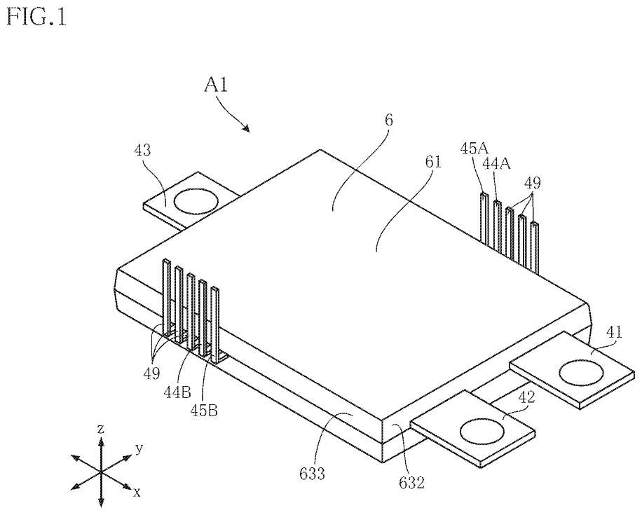

FIGS. 1 to 6 show a semiconductor device A1 according to a first embodiment. The semiconductor device A1 includes a plurality of first semiconductor elements 11, a plurality of second semiconductor elements 12, a supporting substrate 2, a plurality of terminals, a plurality of connecting members, and a sealing member 6. The plurality of terminals include a plurality of power terminals 41 to 43 and a plurality of signal terminals 44A, 44B, 45A, 45B, and 49. The plurality of connecting members include a plurality of connecting members 51A, 51B, 52A, 52B, 531A, 531B, 541A, and 541B.

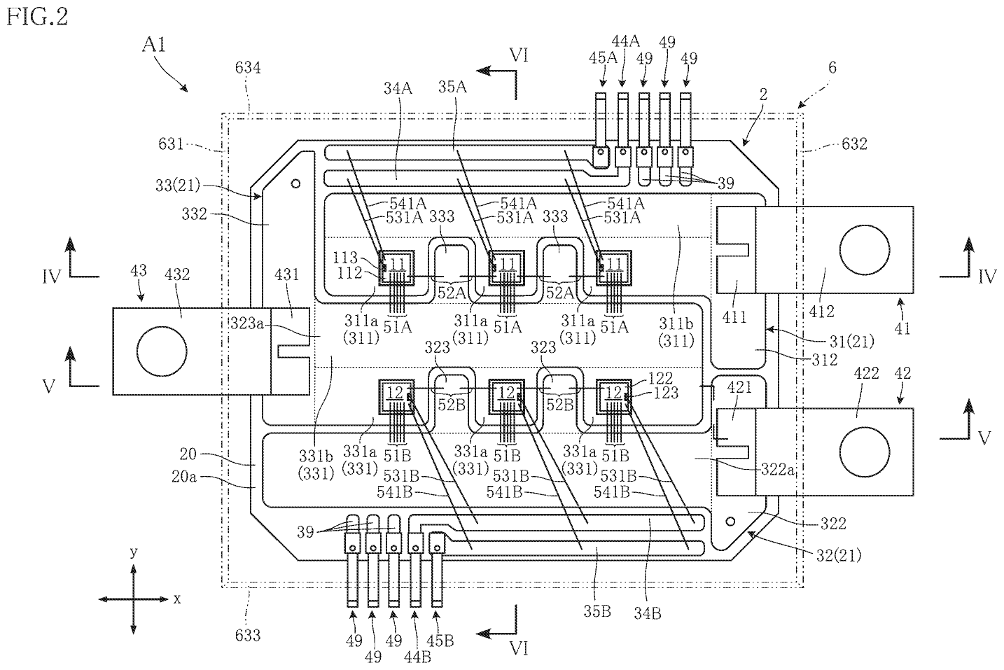

For the convenience of description, the thickness direction of the semiconductor device A1 is referred to as a “thickness direction z”. A first sense of the thickness direction z may be referred to as “upward” and a second sense as “downward”. Note that the terms, including “up”, “down”, “upward”, “downward”, “upper surface” and “lower surface”, are used to describe the relative positions of elements and components with respect to the z direction, and not necessarily with respect to the gravitational vertical. The phrase “in plan view” used in the description below refers to the view as seen in the thickness direction z. A direction orthogonal to the thickness direction z is referred to as a “first direction x”. In one example, the first direction x is the lateral direction in plan view of the semiconductor device A1 (see FIG. 2). The direction orthogonal to the thickness direction z and the first direction x is referred to as a “second direction y”. In the illustrated example, the second direction y is the vertical direction in plan view of the semiconductor device A1 (see FIG. 2).

The first semiconductor elements 11 and the second semiconductor elements 12 may be MOSFETS, for example. Alternatively to MOSFETs, the first semiconductor elements 11 and the second semiconductor elements 12 may be other switching elements, including field effect transistors, such as metal-insulator-semiconductor FETs (MISFETs), and bipolar transistors, such as IGBTs. The first semiconductor elements 11 and the second semiconductor elements 12 are made of silicon carbide (Sic). The semiconductor material, however, is not limited to SiC and may be silicon (Si), gallium arsenide (GaAs), gallium nitride (GaN) or gallium oxide (Ga₂O₃).

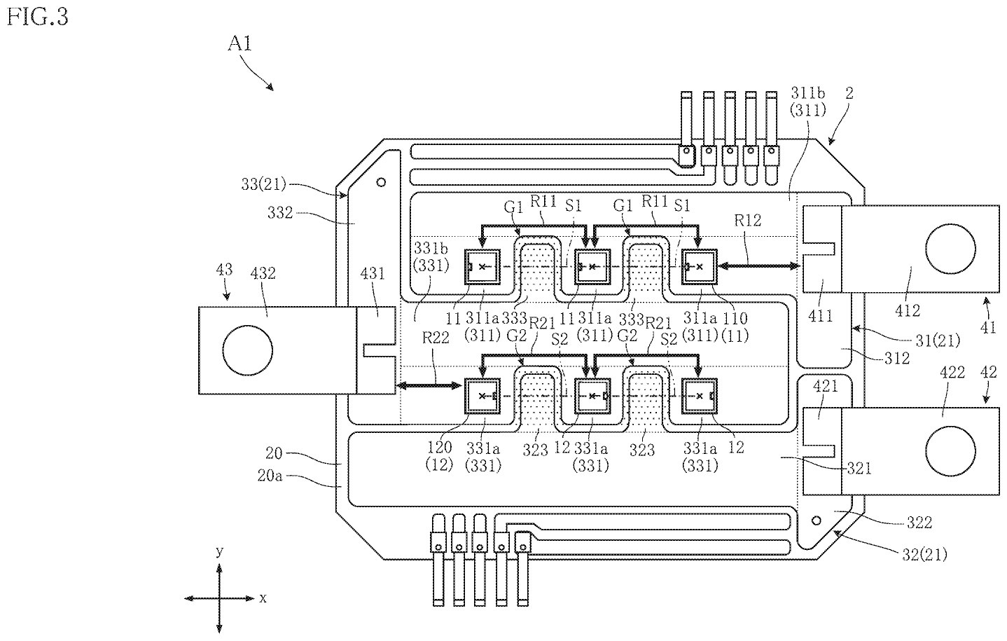

The first semiconductor elements 11 are bonded to the supporting substrate 2 (a power wiring section 31 described later) via a conductive bonding material. Examples of the conductive bonding material include solder, metal paste, and sintered metal. As shown in FIGS. 2 to 4, the first semiconductor elements 11 are arranged at equal intervals in the first direction x, for example. As shown in FIG. 3, the first semiconductor elements 11 include a first proximity element 110. The first proximity element 110 is the one among the first semiconductor elements 11 with the shortest conduction distance to the power terminal 41.

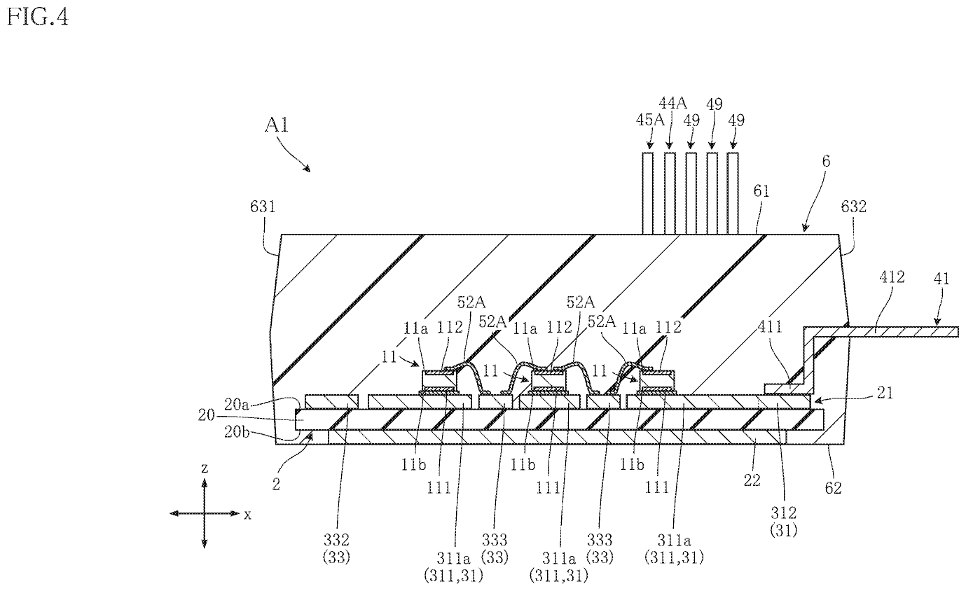

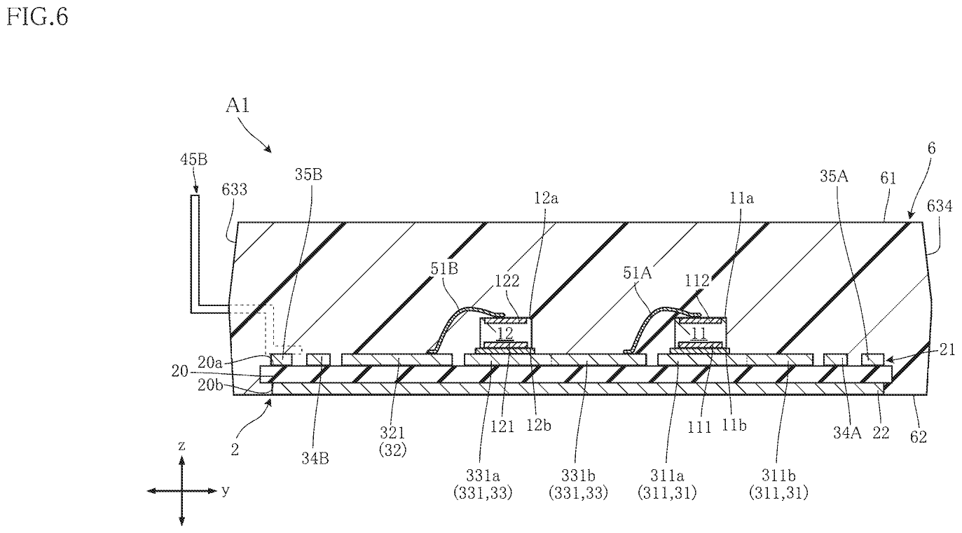

Each first semiconductor element 11 has a first-element obverse surface 11a and a first-element reverse surface 11b. As shown in FIGS. 4 and 6, the first-element obverse surface 11a and the first-element reverse surface 11b are spaced apart from each other in the thickness direction z. The first-element obverse surface 11a faces in the first sense of the thickness direction z (upward), and the first-element reverse surface 11b faces in the second sense of the thickness direction z (downward). The first-element reverse surface 11b faces the supporting substrate 2 (the power wiring section 31 described later).

Each first semiconductor element 11 includes a first electrode 111, a second electrode 112, and a third electrode 113. For each first semiconductor element 11 being an MOSFET, the first electrode 111 is a drain, the second electrode 112 is a source, and the third electrode 113 is a gate. As can be seen from FIGS. 2, 4, and 6, in each first semiconductor element 11, the first electrode 111 is disposed on the first-element reverse surface 11b, whereas the second electrode 112 and the third electrode 113 are disposed on the first-element obverse surface 11a.

For each first semiconductor element 11, a first drive signal (e.g., gate voltage) is applied to the third electrode 113 (gate). In response to the first drive signal, the first semiconductor element 11 switches between the on-state (conducting state) and the off-state (non-conducting state). This switching between the on- and off-states is referred to as switching operation. In the on-state, the forward current flows from the first electrode 111 (drain) to the second electrode 112 (source), and the current does not flow in the off-state. For the first semiconductor element 11, the conduction between the first electrode 111 (drain) and the second electrode 112 (source) is controlled to turn on and off by the first drive signal (e.g., the gate voltage) applied to the third electrode 113. The switching frequency of the first semiconductor element 11 depends on the frequency of the first drive signal.

The first semiconductor elements 11 are configured as described below such that the first electrodes 111 (drains) are electrically connected to each other, and the second electrodes 112 (sources) are electrically connected to each other. That is, the first semiconductor elements 11 are electrically connected in parallel. The semiconductor device A1 inputs a common first drive signal to the first semiconductor elements 11 connected in parallel to operate the first semiconductor elements 11 in parallel.

The second semiconductor elements 12 are bonded to the supporting substrate 2 (a power wiring section 33 described later) via a conductive bonding material. Examples of the conductive bonding material include solder, metal paste, and sintered metal. As shown in FIGS. 2, 3, and 5, the second semiconductor elements 12 are arranged at equal intervals in the first direction x, for example. As shown in FIG. 3, the second semiconductor elements 12 include a second proximity element 120. The second proximity element 120 is the one among the second semiconductor elements 12 with the shortest conduction distance to the power terminal 43.

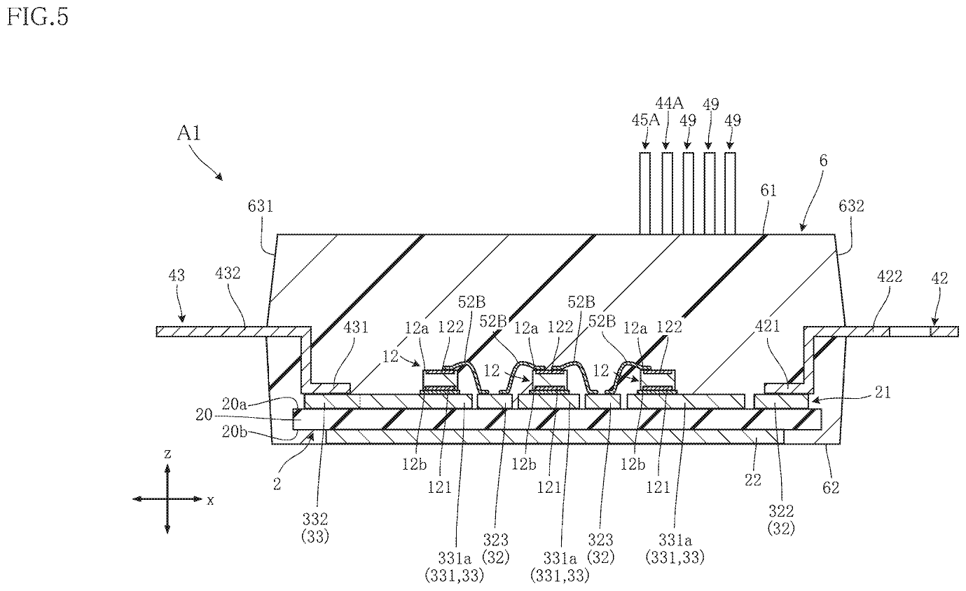

Each second semiconductor element 12 has a second-element obverse surface 12a and a second-element reverse surface 12b. As shown in FIGS. 5 and 6, the second-element obverse surface 12a and the second-element reverse surface 12b are spaced apart from each other in the thickness direction z. The second-element obverse surface 12a faces in the first sense of the thickness direction z (upward), and the second-element reverse surface 12b faces in the second sense of the thickness direction z (downward). The second-element reverse surface 12b faces the supporting substrate 2 (the power wiring section 33 described later).

Each second semiconductor element 12 includes a fourth electrode 121, a fifth electrode 122, and a sixth electrode 123. For each second semiconductor element 12 being an MOSFET, the fourth electrode 121 is a drain, the fifth electrode 122 is a source, and the sixth electrode 123 is a gate. As can be seen from FIGS. 2, 5, and 6, in each second semiconductor element 12, the fourth electrode 121 is disposed on the second-element reverse surface 12b, whereas the fifth electrode 122 and the sixth electrode 123 are disposed on the second-element obverse surface 12a.

For each second semiconductor element 12, a second drive signal (e.g., gate voltage) is applied to the sixth electrode 123 (gate). In response to the second drive signal, the second semiconductor element 12 switches between the on- and off-states. In the on-state, the forward current flows from the fourth electrode 121 (drain) to the fifth electrode 122 (source), and the current does not flow in the off-state. For the second semiconductor element 12, the conduction between the fourth electrode 121 (drain) and the fifth electrode 122 (source) is controlled to turn on and off by the second drive signal (e.g., the gate voltage) applied to the sixth electrode 123. The switching frequency of the second semiconductor element 12 depends on the frequency of the second drive signal.

The second semiconductor elements 12 are configured as described below such that the fourth electrodes 121 (drains) are electrically connected to each other, and the fifth electrodes 122 (sources) are electrically connected to each other. That is, the second semiconductor elements 12 are electrically connected in parallel. The semiconductor device A1 inputs a common second drive signal to the second semiconductor elements 12 connected in parallel to operate the second semiconductor elements 12 in parallel.

The supporting substrate 2 supports first the semiconductor elements 11 and the second semiconductor elements 12 and electrically connects the first semiconductor elements 11 and the second semiconductor elements 12 to a plurality of terminals. For the semiconductor device A1, the supporting substrate 2 may be a direct bonded copper (DBC). In a different configuration, the supporting substrate 2 may be a direct bonded aluminum (DBA). The supporting substrate 2 includes an insulating substrate 20, an obverse-surface metal layer 21, and a reverse-surface metal layer 22.

The insulating substrate 20 may be made of a ceramic material with excellent thermal conductivity. Examples of such ceramic materials include aluminum nitride (AlN), silicon nitride (SiN), and aluminum oxide (Al₂O₃). The insulating substrate 20 is a flat plate, for example. As shown in FIGS. 2 and 3, the insulating substrate 20 is rectangular in plan view, for example.

The insulating substrate 20 has an obverse surface 20a and a reverse surface 20b. As shown in FIGS. 4 to 6, the obverse surface 20a and the reverse surface 20b are spaced apart in the thickness direction z. The obverse surface 20a faces upward and the reverse surface 20b faces downward in the thickness direction z.

Each of the obverse-surface metal layer 21 and the reverse-surface metal layer 22 is made of copper or a copper alloy, for example. In another example, each of the obverse-surface metal layer 21 and the reverse-surface metal layer 22 may be made of aluminum or an aluminum alloy. As shown in FIGS. 4 to 6, the obverse-surface metal layer 21 is formed on the obverse surface 20a, and the reverse-surface metal layer 22 is formed on the reverse surface 20b. The reverse-surface metal layer 22 has a lower surface (the surface facing downward in the thickness direction z) exposed from the sealing member 6. In a different configuration, the lower surface of the reverse-surface metal layer 22 may be covered with the sealing member 6.

As shown in FIG. 2, the obverse-surface metal layer 21 includes a plurality of power wiring sections 31 to 33 and a plurality of signal wiring sections 34A, 34B, 35A, 35B, and 39. The power wiring sections 31 to 33 and the signal wiring sections 34A, 34B, 35A, 35B, and 39 are spaced apart from each other.

The power wiring sections 31, 32 and 33 form conduction paths for the main circuit current of the semiconductor device A1. The main circuit current includes a first main circuit current and a second main circuit current. The first main circuit current is the current that flows between the power terminals 41 and 43. The second main circuit current is the current that flows between the power terminals 43 and 42. In the present embodiment, the power wiring section 31 is an example of a “first conductor”, the power wiring section 32 is an example of a “third conductor”, and the power wiring section 33 is an example of a “second conductor”.

The power wiring section 31 is electrically connected to the first electrodes 111 (drains) of the first semiconductor elements 11. The power wiring section 31 is electrically connected to the power terminal 41. As shown in FIG. 3, the power wiring section 31 is disposed to avoid being located on a portion of each first line segment S1 in plan view. Each first line segment S1 is an auxiliary line shown in FIG. 3 for the convenience of description and defied by connecting the centers of two adjacent first semiconductor element 11 in the first direction x. Note that the center of a first semiconductor element 11 may refer to the center of the whole first semiconductor element 11 in plan view or the center of the first electrode 111 in plan view. For the convenience of description, FIG. 3 indicates the center with an “x” mark. In one example, the power wiring section 31 is disposed to avoid being located on at least 15% and at most 90% (preferably at least 25% and at most 90%) of each first line segment S1 in plan view. The power wiring section 31 includes two pad portions 311 and 312. As shown in FIGS. 2 and 3, the pad portions 311 and 312 are connected to each other and integrally formed.

The pad portion 311 includes a plurality of mounting portions 311a and a connecting portion 311b.

As shown in FIGS. 2 and 3, one first semiconductor element 11 is mounted on each mounting portion 311a, and the first electrode 111 (drain) of the first semiconductor element 11 is bonded to the mounting portion 311a. In plan view, each mounting portion 311a is rectangular, for example. Each mounting portion 311a includes a portion overlapping with the relevant first semiconductor element 11 and a portion extending therebeyond in plan view. As shown in FIG. 3, the mounting portions 311a are arranged along the first direction x at spaced intervals in the first direction x. Each mounting portion 311a is connected to the connecting portion 311b at the end in a first sense of the second direction y. Hence, the mounting portions 311a are electrically connected to each other via the connecting portion 311b. In the present embodiment, the mounting portions 311a are examples of a “first mounting portion”.

As shown in FIG. 3, the mounting portions 311a are arranged along the first direction x with a first gap G1 interposed between any two mounting portions 311a adjacent in the first direction x. For the convenience of description, each first gap G1 is indicated by a doted area in FIG. 3. As shown in FIG. 3, each first gap G1 overlaps with a first line segment S1. Each first gap G1 is provided by, for example, forming a recess in the edge of the pad portion 311 in a second sense of the second direction y (the edge closer to the power wiring section 33). Within each first gap G1, a portion of the power wiring section 33 (a projecting portion 333 described later) is placed.

As shown in FIGS. 2 and 3, the connecting portion 311b is connected to the mounting portions 311a. The connecting portion 311b extends from the pad portion 312 in a second sense of the first direction x. The second sense of the first direction x is opposite to the direction in which the power terminal 41 extends with respect to the pad portion 312 and thus toward the side where the first semiconductor elements 11 are located. The connecting portion 311b has a strip shape in plan view. As shown in FIGS. 2 and 3, the connecting portion 311b is located on the side opposite to the second semiconductor elements 12 in the second direction y with respect to the mounting portions 311a. Also, the connecting portion 311b is located in the first sense of the second direction y from the first line segments S1 (on the side opposite to the second semiconductor elements 12) in plan view. In the present embodiment, the connecting portion 311b is an example of a “first connecting portion”.

As shown in FIGS. 2 to 4, the pad portion 312 is where the power terminal 41 is bonded. As shown in FIGS. 2 and 3, the pad portion 312 has a strip shape extending in the second direction y in plan view. The pad portion 312 is connected to end of the pad portion 311 in a first sense of the first direction x (the end closer to the power terminal 41).

The power wiring section 32 is electrically connected to the fifth electrodes 122 (sources) of the second semiconductor elements 12. The power wiring section 32 is electrically connected to the power terminal 42. The power wiring section 32 includes two pad portions 321 and 322 and a plurality of projecting portions 323. In a different configuration, the power wiring section 32 may be without any projecting portion 323. As shown in FIGS. 2 and 3, the pad portions 321 and 322 and the projecting portions 323 are connected to each other and integrally formed.

As shown in FIGS. 2 and 6, the pad portion 321 is electrically connected to the fifth electrodes 122 (sources) of the second semiconductor elements 12 via the connecting members 51B bonded to the pad portion 321. As shown in FIGS. 2 and 3, the pad portion 321 extends from the pad portion 322 in the second sense of the first direction x. The second sense of the first direction x is opposite to the direction in which the power terminal 42 extends with respect to the pad portion 322 and thus toward the side where the first semiconductor elements 11 and the second semiconductor elements 12 are located. The pad portion 321 has a strip shape extending, for example, in the first direction x in plan view. The pad portion 321 is located in the second sense of the second direction y (downward in FIG. 2) from the pad portion 311.

As shown in FIGS. 2, 3, and 5, the pad portion 322 is where the power terminal 42 is bonded. As shown in FIGS. 2 and 3, the pad portion 322 has a strip shape extending in the second direction y in plan view. The pad portion 322 is connected to end of the pad portion 321 in the first sense of the first direction x (the end closer to the power terminal 42). The pad portion 322 is located in the second sense of the second direction y (downward in FIG. 2) from the pad portion 312.

As shown in FIGS. 2 and 3, each projecting portion 323 protrudes in the first sense of the second direction y from the end of the pad portion 321 in the first sense of the second direction y. The first sense of the second direction is the direction toward the side where the second semiconductor elements 12 are located with respect to the pad portion 321. In plan view, each projecting portion 323 is rectangular, for example. Each projecting portion 323 is located between two second semiconductor elements 12 adjacent in the first direction x and between two mounting portions 331a adjacent in the first direction x. As shown in FIG. 3, each projecting portion 323 overlaps in part with a second gap G2 (described later) in plan view.

The power wiring section 33 is electrically connected to the second electrodes 112 (sources) of the first semiconductor elements 11 and also to the fourth electrodes 121 (drains) of the second semiconductor elements 12. The power wiring section 33 is electrically connected to the power terminal 43. As shown in FIG. 3, the power wiring section 33 is disposed to avoid being located on a portion of each second line segment S2 in plan view (see FIG. 3). Each second line segment S2 is an auxiliary line shown in FIG. 3 for the convenience of description and defined by connecting the centers of two adjacent second semiconductor elements 12 in the first direction x. Note that the center of a second semiconductor element 12 may refer to the center of the whole second semiconductor element 12 in plan view or the center of the fourth electrode 121 in plan view. For the convenience of description, FIG. 3 indicates the center with an “x” mark. In one example, the power wiring section 33 is disposed to avoid being located on at least 15% and at most 90% (preferably at least 25% and at most 90%) of each second line segment S2 in plan view. The power wiring section 33 includes two pad portions 331 and 332 and a plurality of projecting portions 333. In a different configuration, the power wiring section 33 may be without any projecting portion 333. As shown in FIGS. 2 and 3, the pad portions 331 and 332 and the projecting portions 333 are connected to each other and integrally formed.

The pad portion 331 includes a plurality of mounting portions 331a and a connecting portion 331b.

As shown in FIGS. 2 and 3, one second semiconductor element 12 is mounted on each mounting portion 331, and the fourth electrode 121 (drain) of the second semiconductor element 12 is bonded to the mounting portion 331a. In plan view, each mounting portion 331a is rectangular, for example. Each mounting portion 331a includes a portion overlapping with the relevant second semiconductor element 12 and a portion extending therebeyond. As shown in FIG. 3, the mounting portions 331a are arranged along the first direction x at spaced intervals in the first direction x. Each mounting portion 331a is connected to the connecting portion 331b at the end in the first sense of the second direction y. Hence, the mounting portions 331a are electrically connected to each other via the connecting portion 331b. In the present embodiment, each mounting portion 331a is an example of a “second mounting portion”.

As shown in FIG. 3, the mounting portions 331a are arranged along the first direction x with a second gap G2 interposed between any two mounting portions 331a adjacent in the first direction x. For the convenience of description, each second gap G2 is indicated by a doted area in FIG. 3. Each second gap G2 overlaps with a second line segment S2. Each second gap G2 is provided by, for example, forming a recess in the edge of the pad portion 331 in the second sense of the second direction y (the edge closer to the power wiring section 32). Within each second gap G2, a portion of the power wiring section 32 (a projecting portion 323) is placed.

As shown in FIGS. 2 and 3, the connecting portion 331b is connected to the mounting portions 331a. The connecting portion 331b extends from the pad portion 332 in the first sense of the first direction x. The first sense of the first direction x is opposite to the direction in which the power terminal 43 extends with respect to the pad portion 332 and thus toward the side where the second semiconductor elements 12 are located. The connecting portion 331b has a strip shape in plan view. As shown in FIGS. 2 and 6, the connecting portion 331b is electrically connected to the second electrodes 112 (sources) of the first semiconductor elements 11 via the connecting members 51A bonded to the connecting portion 331b. As shown in FIGS. 2 and 3, the connecting portion 331b is located on the same side as the first semiconductor elements 11 in the second direction y with respect to the mounting portions 331a. Also, the connecting portion 331b is located in the first sense of the second direction y (on the same side as the first semiconductor elements 11) from the second line segments S2 in plan view. In the present embodiment, the connecting portion 331b is an example of a “second connecting portion”.

As shown in FIGS. 2 and 3, the pad portion 332 is where the power terminal 43 is bonded. The pad portion 332 has a strip shape extending in the second direction y in plan view. The pad portion 332 is connected to end of the pad portion 331 in the second sense of the first direction x (the end closer to the power terminal 43).

As shown in FIGS. 2 and 3, each projecting portion 333 protrudes in the first sense of the second direction y from the end of the connecting portion 331b (the pad portion 331) in the first sense of the second direction y in plan view. The first sense of the second direction y is the direction toward the side where the first semiconductor elements 11 are located with respect to the connecting portion 331b. In plan view, each projecting portion 333 is rectangular, for example. Each projecting portion 333 is located between two first semiconductor elements 11 adjacent in the first direction x and between two mounting portions 311a adjacent in the first direction x. Thus, as shown in FIG. 3, each projecting portion 333 overlaps in part with a first gap G1 in plan view.

The signal wiring sections 34A, 34B, 35A, and 35B form conduction paths for the electrical signal that controls the semiconductor device A1.

As shown in FIG. 2, the signal wiring section 34A is electrically connected to the third electrodes (gates) 113 of the first semiconductor elements 11 via the connecting members 531A bonded thereto. The signal wiring section 34A passes a first drive signal. To the signal wiring section 34A, the signal terminal 44A is bonded.

As shown in FIG. 2, the signal wiring section 34B is electrically connected to the sixth electrodes 123 (gates) of the second semiconductor elements 12 via the connecting members 531B bonded thereto. The signal wiring section 34B passes a second drive signal. To the signal wiring section 34B, the signal terminal 44B is bonded.

As shown in FIG. 2, the signal wiring section 34A and the signal wiring section 34B are located opposite to each other in the second direction y with respect to the pad portions 311, 321 and 331. The signal wiring section 34A is located opposite to the pad portion 331 in the second direction y with respect to the pad portion 311. The signal wiring section 34B is located opposite to the pad portion 331 in the second direction y with respect to the pad portion 321.

As shown in FIG. 2, the signal wiring section 35A is electrically connected to the second electrodes (sources) 112 of the first semiconductor elements 11 via the connecting members 541A bonded thereto. The signal wiring section 35A passes a first detection signal. The first detection signal is an electrical signal indicating the conducting state of each first semiconductor element 11, such as a voltage signal corresponding to the current (source current) flowing through the second electrode 112 (source). To the signal wiring section 35A, the signal terminal 45A is bonded.

As shown in FIG. 2, the signal wiring section 35B is electrically connected to the fifth electrodes 122 (sources) of the second semiconductor elements 12 via the connecting members 541A bonded thereto. The signal wiring section 35B passes a second detection signal. The second detection signal is an electrical signal indicating the conducting state of each second semiconductor element 12, such as a voltage signal corresponding to the current (source current) flowing through the fifth electrode 122 (source). The signal terminal 45B is bonded to the signal wiring section 35B.

As shown in FIG. 2, the signal wiring sections 35A and 35B are located opposite to each other in the second direction y with respect to the pad portions 311, 321 and 331. The signal wiring section 35A is located on the same side as the signal wiring section 34A with respect to the pad portion 311 in the second direction y. The signal wiring section 35B is located on the same side as the signal wiring section 34B in the second direction y with respect to the pad portion 321.

The signal wiring sections 39 are not electrically connected to any of the first semiconductor elements 11 and the second semiconductor elements 12. That is, any main circuit current or electrical signal does not flow through the signal wiring sections 39.

As shown in FIGS. 1 and 2, the power terminals 41 to 43 and the signal terminals 44A, 44B, 45A, 45B, and 49 each have a portion exposed from the sealing member 6. The power terminals 41 to 43 and the signal terminals 44A, 44B, 45A, 45B, and 49 are made of, for example but not limited to, copper or a copper alloy. The power terminals 41 to 43 and the signal terminals 44A, 44B, 45A, 45B, and 49 are made of metal plates, which have been bent appropriately.

The power terminals 41 and 42 are connected to a power supply and receive a power supply voltage (for example, direct-current voltage) applied thereto. In one example, the power terminal 41 is a positive-side power input terminal (P terminal), and the power terminal 42 is a negative-side power input terminal (N terminal). The power terminal 43 outputs a voltage (e.g., alternating-current voltage) as converted by the switching operation of the first semiconductor elements 11 and the second semiconductor elements 12. The power terminal 43 is a power output terminal (OUT terminal). For the semiconductor device A1, the main circuit current (a first main circuit current and a second main circuit current) is the current produced by the power supply voltage and the voltage after the power conversion. The power terminal 41 is an example of a “first power terminal”, the power terminal 42 is an example of a “third power terminal”, and the power terminal 43 is an example of a “second power terminal”.

The power terminal 41 is electrically connected to the first electrodes 111 (drains) of the first semiconductor elements 11 via the power wiring section 31. The power terminal 41 includes a bonding portion 411 and a terminal portion 412.

As shown in FIGS. 2 and 3, the bonding portion 411 is covered with the sealing member 6. As shown in FIGS. 2 and 3, the bonding portion 411 is bonded to the pad portion 312 of the power wiring section 31. Hence, the power terminal 41 and the power wiring section 31 are electrically connected. For the bonding of the bonding portion 411 to the pad portion 312, a various techniques can be used including bonding with a conductive bonding material (e.g., solder, sintered metal, etc.), laser bonding, and ultrasonic bonding.

As shown in FIGS. 2 and 3, the terminal portion 412 is exposed from the sealing member 6. As shown in FIG. 2, the terminal portion 412 extends in the first sense of the first direction x from the sealing member 6 in plan view. The surface of terminal portion 412 may be plated with silver, for example.

The power terminal 42 is electrically connected to the fifth electrodes 122 (sources) of the second semiconductor elements 12 via the power wiring section 32. The power terminal 42 includes a bonding portion 421 and a terminal portion 422.

As shown in FIGS. 2 and 3, the bonding portion 421 is covered with the sealing member 6. As shown in FIGS. 2 and 3, the bonding portion 421 is bonded to the pad portion 322 of the power wiring section 32. Hence, the power terminal 42 and the power wiring section 32 are electrically connected. For the bonding of the bonding portion 421 to the pad portion 322, a various techniques can be used including bonding with a conductive bonding material (e.g., solder, sintered metal, etc.), laser bonding, and ultrasonic bonding.

As shown in FIGS. 2 and 3, the terminal portion 422 is exposed from the sealing member 6. As shown in FIG. 2, the terminal portion 422 extends in the first sense of the first direction x from the sealing member 6 in plan view. The surface of the terminal portion 422 may be plated with silver, for example.

The power terminal 43 is electrically connected to the second electrodes 112 (sources) of the first semiconductor elements 11 and the fourth electrodes 121 (drains) of the second semiconductor elements 12 via the power wiring section 33. The power terminal 43 includes a bonding portion 431 and a terminal portion 432.

As shown in FIGS. 2 and 3, the bonding portion 431 is covered with the sealing member 6. As shown in FIGS. 2 and 3, the bonding portion 431 is bonded to the pad portion 332 of the power wiring section 33. Hence, the power terminal 43 and the power wiring section 33 are electrically connected. For the bonding of the bonding portion 431 to the pad portion 332, a various techniques can be used including bonding with a conductive bonding material (e.g., solder, sintered metal, etc.), laser bonding, and ultrasonic bonding.

As shown in FIGS. 2 and 3, the terminal portion 432 is exposed from the sealing member 6. As shown in FIG. 2, the terminal portion 432 extends in the first sense of the first direction x from the sealing member 6 in plan view. The surface of the terminal portion 432 may be plated with silver, for example.

The power terminals 41 and 42 are spaced apart from each other and arranged along the second direction y. The power terminals 41 and 42 are located opposite to the power terminal 43 in the first direction x with respect to the supporting substrate 2. Although the semiconductor device A1 includes one power terminal 43, a semiconductor device of a different configuration may include two or more power terminals 43.

Each of the signal terminals 44A, 44B, 45A, and 45B is either for input or output of an electrical signal for controlling the semiconductor device A1. The signal terminals 44A, 44B, 45A, 45B, and 49 each include a portion covered with the sealing member 6 and a portion exposed from the sealing member 6. The signal terminals 44A, 44B, 45A, 45B, and 49 are pin-like metal members. The metal members are made of copper or a copper alloy, for example.

As shown in FIG. 2, the signal terminal 44A is bonded to the signal wiring section 34A at the portion covered with the sealing member 6. Since the signal wiring section 34A is electrically connected to the third electrodes 113 (gates) of the first semiconductor elements 11, the signal terminal 44A is electrically connected to the third electrodes 113 (gates) of the first semiconductor elements 11. The signal terminal 44A is for input terminal of the first drive signal.

As shown in FIG. 2, the signal terminal 44B is bonded to the signal wiring section 34B at the portion covered with the sealing member 6. Since the signal wiring section 34B is electrically connected to the sixth electrodes 123 (gates) of the second semiconductor elements 12, the signal terminal 44B is electrically connected to the sixth electrodes 123 (gates) of the second semiconductor elements 12. The signal terminal 44B is for input of the second drive signal.

As shown in FIG. 2, the signal terminal 45A is bonded to the signal wiring section 35A at the portion covered with the sealing member 6. Since the signal wiring section 35A is electrically connected to the second electrodes 112 (sources) of the first semiconductor elements 11, the signal terminal 45A is electrically connected to the second electrodes 112 (sources) of the first semiconductor elements 11. The signal terminal 45A is for output of the first detection signal.

As shown in FIG. 2, the signal terminal 45B is bonded to the signal wiring section 35B at the portion covered with the sealing member 6. Since the signal wiring section 35B is electrically connected to the fifth electrodes 122 (sources) of the second semiconductor elements 12, the signal terminal 45B is electrically connected to the fifth electrodes 122 (sources) of the second semiconductor elements 12. The signal terminal 45B is for output of the second drive signal.

As shown in FIG. 2, each signal terminal 49 is bonded to a signal wiring section 39 at the portion covered with the sealing member 6. The signal terminals 49 are not electrically connected to any of the first semiconductor elements 11 and the second semiconductor elements 12. That is, the signal terminals 49 are no-connection terminals. The signal terminals 49 may be omitted.

The connecting members 51A, 51B, 52A, 52B, 531A, 531B, 541A, and 541B each electrically connect two isolated portions. In the semiconductor device A1, the connecting members 51A, 51B, 52A, 52B, 531A, 531B, 541A, and 541B are bonding wires. The material of the connecting members 51A, 51B, 52A, 52B, 531A, 531B, 541A, and 541B may be any of gold, copper, or aluminum.

As shown in FIGS. 2 and 6, each connecting member 51A is bonded to the second electrode 112 (source) of a first semiconductor element 11 and the connecting portion 331b of the pad portion 331 to electrically connect the second electrode 112 and the power wiring section 33. In the semiconductor device A1 as shown in FIG. 2, a plurality of connecting members 51A are bonded to each second electrode 112. The main circuit current (the first main circuit current) of the semiconductor device A1 flows through the connecting members 51A. For the semiconductor device A1, the connecting members 51A may be plates of metal (e.g., copper) instead of the bonding wires. In such a case, one connecting member 51A may be sufficient to connect each second electrode 112 to the pad portion 331. Each connecting member 51A is an example of a “first connecting member”.

As shown in FIGS. 2 and 6, each connecting member 51B is bonded to the fifth electrode 122 (source) of a second semiconductor element 12 and the pad portion 321 to electrically connect the fifth electrode 122 and the power wiring section 32. In the semiconductor device A1 as shown in FIG. 2, a plurality of connecting members 51B are bonded to each fifth electrode 122. The main circuit current (the second main circuit current) of the semiconductor device A1 flows through the connecting members 51B. For the semiconductor device A1, the connecting members 51B may be plates of metal (e.g., copper) instead of the bonding wires. In such a case, one connecting member 51B may be sufficient to connect each fifth electrode 122 to the pad portion 321. Each connecting member 51B is an example of a “second connecting member”.

As shown in FIGS. 2 and 4, each connecting member 52A is bonded to the second electrode 112 (source) of a first semiconductor element 11 and the projecting portion 333 adjacent to that first semiconductor element 11 in the first direction x to provide electrical connection between them. Two connecting members 52A are bonded to each projecting portion 333. In plan view, the connecting members 52A extend in the first direction x, for example. In the case where the power wiring section 33 does not have the projecting portions 333, the connecting members 52A may be omitted or may be bonded directly to the second electrodes 112 of two first semiconductor elements 11 adjacent in the first direction x.

As shown in FIGS. 2 and 5, each connecting member 52B is bonded to the fifth electrode 122 (source) of a second semiconductor element 12 and the projecting portion 323 adjacent to that second semiconductor element 12 in the first direction x to provide electrical connection between them. Two connecting members 52B are bonded to each projecting portion 323. In plan view, the connecting members 52B extend in the first direction x, for example. In the case where the power wiring section 32 does not have the projecting portions 323, the connecting members 52B may be omitted or may be directly bonded to the fifth electrodes 122 of two second semiconductor elements 12 adjacent in the first direction x.

As shown in FIG. 2, each connecting member 531A is bonded to the third electrode 113 (gate) of a first semiconductor element 11 and the signal wiring section 34A to provide electrical connection between the third electrode 113 and the signal wiring section 34A. Consequently, the signal terminal 44A is electrically connected to the third electrodes 113 of the first semiconductor elements 11 via the signal wiring section 34A and the connecting members 531A.

As shown in FIG. 2, each connecting member 531B is bonded to the sixth electrode 123 (gate) of a second semiconductor element 12 and the signal wiring section 34B to provide electrical connection between the sixth electrode 123 and the signal wiring section 34B. Consequently, the signal terminal 44B is electrically connected to the sixth electrodes 123 of the second semiconductor elements 12 via the signal wiring section 34B and the connecting members 531B.

As shown in FIG. 2, each connecting member 541A is bonded to the second electrode 112 (source) of a first semiconductor element 11 and the signal wiring section 35A to provide electrical connection between the second electrode 112 and the signal wiring section 35A. Consequently, the signal terminal 45A is electrically connected to the second electrodes 112 of the first semiconductor elements 11 via the signal wiring section 35A and the connecting members 541A.

As shown in FIG. 2, each connecting member 541B is bonded to the fifth electrode 122 (source) of a second semiconductor element 12 and the signal wiring section 35B to provide electrical connection between the fifth electrode 122 and the signal wiring section 35B. Consequently, the signal terminal 45B is electrically connected to the fifth electrodes 122 of the second semiconductor elements 12 via the signal wiring section 35B and the connecting members 541B.

The sealing member 6 is an encapsulating body for protecting the first semiconductor elements 11 and the second semiconductor element 12. The sealing member 6 covers the first semiconductor elements 11, the second semiconductor elements 12, a portion of the supporting substrate 2, the power terminals 41 to 43, the signal terminals 44A, 44B, 45A, 45B, and 49, and the connecting members 51A, 51B, 52A, 52B, 531A, 531B, 541A, and 541B. The sealing member 6 may be made of an insulating resin material, such as an epoxy resin. The sealing member 6 may be black. The sealing member 6 is rectangular in plan view. The sealing member 6 has a resin obverse surface 61, a resin reverse surface 62, and a plurality of resin side surfaces 631 to 634.

As shown in FIGS. 4 to 6, the resin obverse surface 61 and the resin reverse surface 62 are spaced apart in the thickness direction z. The resin obverse surface 61 faces upward, and the resin reverse surface 62 faces downward in the thickness direction z. The resin side surfaces 631 to 634 are located between, and connected to the resin obverse surface 61 and the resin reverse surface 62. As shown in FIGS. 4 and 5, the resin side surfaces 631 and 632 are a pair of surfaces facing away from each other in the first direction X. The power terminals 41 and 42 protrude from the resin side surface 632, whereas the power terminal 43 protrudes from the resin side surface 631. As shown in FIG. 6, the resin side surfaces 633 and 634 are a pair of surfaces facing away from each other in the second direction y. The signal terminals 44A and 45A protrude from the resin side surface 634, whereas the signal terminals 44B and 45B protrude from the resin side surface 633.

In the semiconductor device A1, a conduction path R11 between the first electrodes 111 (drains) of each two first semiconductor elements 11 adjacent in the first direction x (see FIG. 3) is longer than a conduction path R12 between the first electrode 111 (drain) of the first proximity element 110 and the power terminal 41 (P terminal) (see FIG. 3). Consequently, the element-to-element inductance L1, which is the inductance of the conduction path R11, is greater than the element-to-terminal inductance L2, which is the inductance of the conduction path R12. The element-to-element inductance L1 is an example of a “first inductance”, and the element-to-terminal inductance L2 is an example of a “second inductance”.

Similarly, in the semiconductor device A1, a conduction path R21 between the fourth electrodes 121 (drains) of each two second semiconductor elements 12 adjacent in the first direction x (see FIG. 3) is longer than a conduction path R22 between the fourth electrode 121 (drain) of the second proximity element 120 and the power terminal 43 (OUT terminal) (see FIG. 3). Consequently, the element-to-element inductance L3, which is the inductance of the conduction path R21, is greater than the element-to-terminal inductance L4, which is the inductance of the conduction path R22. The element-to-element inductance L3 is an example of a “third inductance”, and the element-to-terminal inductance L4 is an example of a “fourth inductance”.

The operation and effect of the semiconductor device A1 are as follows.

The semiconductor device A1 includes the first semiconductor elements 11, and the first semiconductor elements 11 are electrically connected in parallel. The semiconductor device A1 includes the power wiring section 31 as a first conductor. As viewed in the thickness direction z, the power wiring section 31 is disposed to avoid being located on a portion of each first line segment S1. This configuration increases the element-to-element inductance L1 as compared with a configuration in which the power wiring section 31 is disposed without avoiding the first line segments S1 (hereinafter, a “first comparative configuration”). In the first comparative configuration, a linear conduction path is formed between the first electrodes 111 (drains) of the first semiconductor elements 11 as in JP-A-2016-225493. The research by the present inventors has found that the greater the inductance is between the first electrodes 111 (drains) of the first semiconductor elements 11, the more efficiently the oscillation phenomenon can be suppressed. The semiconductor device A1 can therefore suppress the oscillation phenomenon during the parallel operation of the first semiconductor elements 11 more efficiently than the first comparative configuration.

In the semiconductor device A1, the power wiring section 31 as a first conductor is disposed to avoid being located on at least 15% of each first line segment S1. This configuration provides a sufficiently long conduction path R11 relative to each first line segment S1. Consequently, an appropriate element-to-element inductance L1 is obtained for suppressing the oscillation phenomenon during the parallel operation of the first semiconductor elements 11. In particular, when the power wiring section 31 is disposed to avoid being located on at least 25% of each first line segment S1 as viewed in the thickness direction z, the resulting element-to-element inductance L1 is more appropriate for suppressing the oscillation phenomenon during the parallel operation of the first semiconductor elements 11. Notably, in addition, the power wiring section 31 is disposed to avoid being located on at most 90% of each first line segment S1 as viewed in the thickness direction z. Unlike this configuration, a power wiring section 31 that is disposed to avoid more than 90% of each first line segment S1 may present a risk of a first semiconductor element 11 being placed to extend out of the relevant mounting portion 311a as viewed in the thickness direction z. If a first semiconductor element 11 extends out of the relevant mounting portion 311a as viewed in the thickness direction z, the bonding strength of the first semiconductor element 11 may be reduced or the bonding area between the first electrode 111 and the mounting portion 311a may be reduced. In contrast, the power wiring section 31 of the semiconductor device A1 is disposed such that the portion of each first line segment S1 not overlapping with the power wiring section 31 as viewed in the thickness direction z is at most 90%, providing sufficient regions (the mounting portions 311a) for mounting the first semiconductor elements 11. That is, the semiconductor device A1 can reduce the possibility that a first semiconductor element 11 is placed to extend out of the relevant mounting portion 311a. This consequently prevent reducing the bonding strength of each first semiconductor element 11 and reducing the bonding area between each first electrode 111 and a relevant mounting portion 311a. In view of the above, with the power wiring section 31 as a first conductor disposed to avoid being located on at least 15% and at most 90% of each first line segment S1, the semiconductor device A1 can obtain an appropriate element-to-element inductance L1 and ensure that the first semiconductor elements 11 are appropriately bonded to the mounting portions 311a.

In the semiconductor device A1, the power wiring section 31 includes the plurality of mounting portions 311a for mounting the plurality of first semiconductor elements 11. The mounting portions 311a are arranged along the first direction x with a first gap G1 interposed between any two mounting portions 311a adjacent in the first direction x. As viewed in the thickness direction z, the first gap G1 intersects the first line segment S1. With this configuration, the power wiring section 31 is shaped to avoid a portion of each first line segment S1. The semiconductor device A1 can therefore increase the element-to-element inductance L1 as compared with the first comparative configuration described above.

The semiconductor device A1 includes the second semiconductor elements 12, and the second semiconductor elements 12 are electrically connected in parallel. The semiconductor device A1 includes the power wiring section 33 as a second conductor. As viewed in the thickness direction z, the power wiring section 33 is disposed to avoid being located on a portion of each second line segment S2. This configuration increases the element-to-element inductance L3 as compared with a configuration in which the power wiring section 33 is disposed without avoiding the second line segments S2 (hereinafter, a “second comparative configuration”). In the second comparative configuration, a linear conduction path is formed between the fourth electrodes 121 (drains) of the second semiconductor elements 12 as in JP-A-2016-225493. The semiconductor device A1 can therefore suppress the oscillation phenomenon during the parallel operation of the second semiconductor elements 12 more efficiently than the second comparative configuration.

In the semiconductor device A1, the power wiring section 33 as a second conductor is disposed to avoid being located on 15% or more of each second line segment S2. This configuration can provide a sufficiently long conduction path R21 relative to each second line segment S2. Consequently, an appropriate element-to-element inductance L3 is obtained for suppressing the oscillation phenomenon during the parallel operation of the second semiconductor elements 12. In particular, when the power wiring section 33 is disposed to avoid being located on at least 25% of each second line segment S2 as viewed in the thickness direction z, the resulting element-to-element inductance L3 more is appropriate for suppressing the oscillation phenomenon during the parallel operation of the second semiconductor elements 12. Notably, in addition, the power wiring section 33 is disposed to avoid being located on at most 90% of each second line segment S2 as viewed in the thickness direction z. Similarly to the power wiring section 31 disposed to avoid at most 90% of each first line segment S1, the power wiring section 33 of this configuration can provide sufficient regions (the mounting portions 331a) for mounting the second semiconductor elements 12. That is, the semiconductor device A1 can reduce the possibility that a second semiconductor element 12 is placed to extend out of the relevant mounting portion 331a. This can consequently prevent reducing the bonding strength of each second semiconductor element 12 and reducing the bonding area between each fourth electrode 121 and a relevant mounting portion 331a. In view of the above, with the power wiring section 33 as a second conductor disposed to avoid being located on at least 15% and at most 90% of each second line segment S2, the semiconductor device A1 can obtain an appropriate element-to-element inductance L3 and ensure that the second semiconductor elements 12 are appropriately bonded to the mounting portions 331a.

In the semiconductor device A1, the power wiring section 33 includes the plurality of mounting portions 331a for mounting the plurality of second semiconductor elements 12. The mounting portions 331a are arranged along the first direction x with a second gap G2 interposed between any two mounting portions 331a adjacent in the first direction x. As viewed in the thickness direction z, the second gap G2 intersects the second segment line S2. With this configuration, the power wiring section 33 is shaped to avoid a portion of each second line segment S2. The semiconductor device A1 can therefore increase the element-to-element inductance L3 as compared with the second comparative configuration described above.

In the semiconductor device A1, the power wiring section 33 includes the projecting portions 333. As viewed in the thickness direction z, the projecting portions 333 protrude from the connecting portion 331b (the pad portion 331) in the second direction y. Each projecting portion 333 overlaps in part with a first gap G1 as viewed in the thickness direction z. With this configuration, each projecting portion 333 is located between two first semiconductor elements 11 adjacent in the first direction x. Consequently, the second electrodes 112 of the two first semiconductor elements 11 flanking a projecting portion 333 in the first direction x can be electrically connected via the projecting portion 333 by using, for example, connecting members 52A. The connecting members 52A connected in this way form a conduction path between the second electrodes 112 of the two first semiconductor elements 11 adjacent in the first direction x, apart from the conduction paths for the main circuit current. The research by the present inventors has found that the smaller the inductance between the second electrodes 112 (sources) of two first semiconductor elements 11 is, the more efficiently the oscillation phenomenon can be suppressed when the two first semiconductor elements 11 are operated in parallel. The semiconductor device A1 can therefore more efficiently suppress the oscillation phenomenon during the parallel operation of the first semiconductor elements 11, by electrically connecting the second electrodes 112 of each two first semiconductor elements 11 flanking a projecting portion 333 in the first direction x via the projecting portion 333 using the connecting members 52A.

In the semiconductor device A1, the power wiring section 32 includes the projecting portions 323. As viewed in the thickness direction z, the projecting portions 323 protrude from the pad portion 322 in the second direction y. Each projecting portion 323 overlaps in part with a second gap G2 as viewed in the thickness direction z. With this configuration, each projecting portion 323 is located between two second semiconductor elements 12 adjacent in the first direction x. Consequently, the fifth electrodes 122 of the two second semiconductor elements 12 flanking a projecting portion 323 in the first direction x can be electrically connected via the projecting portion 323 by using, for example, connecting members 52B. The connecting members 52B connected in this way form a conduction path between the fifth electrodes 122 of the two second semiconductor elements 12 adjacent in the first direction x, apart from the conduction path for the main circuit current. The semiconductor device A1 can therefore more efficiently suppress the oscillation phenomenon during the parallel operation of the second semiconductor elements 12, by electrically connecting the fifth electrodes 122 of each two second semiconductor elements 12 flanking a projecting portion 323 in the first direction x via the projecting portion 323 using the connecting members 52B.

### Variations of First Embodiment

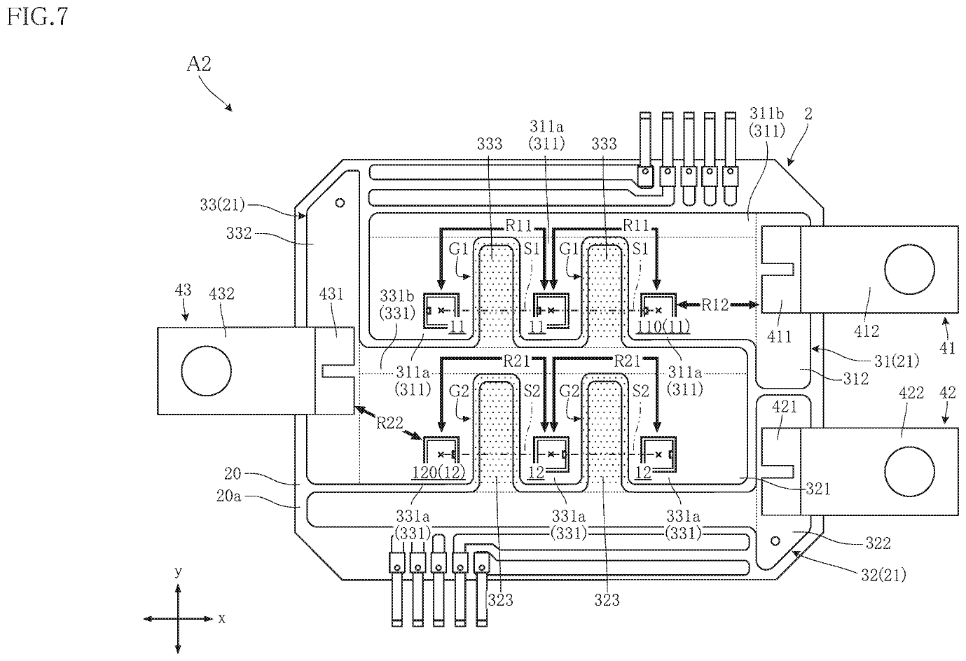

Next, variations of the semiconductor device A1 according to the first embodiment will be described with reference to FIGS. 7 to 10. FIGS. 7 to 10 show semiconductor devices A2 to A5 according to first to fourth variations of the first embodiment.

First, the features of the semiconductor devices A2 to A5 that are common with the semiconductor device A1 and also common with each other will be described.

The semiconductor devices A2 to A5 have the following features in common with the semiconductor device A1. First, as shown in FIGS. 7 to 10, the power wiring section 31 is disposed to avoid being located on a portion of each first line segment S1 as viewed in the thickness direction z. Second, as shown in FIGS. 7 to 10, the power wiring section 33 is disposed to avoid being located on a portion of each second line segment S2 as viewed in the thickness direction z. Third, as shown in FIGS. 7 to 10, two mounting portions 311a are adjacent in the first direction x across a first gap G1, and the first gap G1 intersects the first line segment S1 as viewed in the thickness direction z. Fourth, as shown in FIGS. 7 to 10, two connecting portions 331a are adjacent in the first direction x across a second gap G2, and the second gap G2 intersects the second line segment S2 as viewed in the thickness direction z.

With the first common feature described above, each of the semiconductor devices A2 to A5 can increase the element-to-element inductance L1 as compared with the first comparative configuration described above and similarly to the semiconductor device A1. That is, similarly to the semiconductor device A1, each of the semiconductor devices A2 to A5 outperforms the first comparative configuration in suppressing the oscillation phenomenon during the parallel operation of the first semiconductor elements 11. With the second common feature described above, each of the semiconductor devices A2 to A5 can increase the element-to-element inductance L3 as compared with the second comparative configuration described above and similarly to the semiconductor device A1. That is, similarly to the semiconductor device A1, each of the semiconductor devices A2 to A5 outperforms the second comparative configuration in suppressing the oscillation phenomenon during the parallel operation of the second semiconductor elements 12.

Next, the following sequentially describes the semiconductor devices A2 to A5 according to the first to fourth variations of the first embodiment, respectively.

### First Variation of First Embodiment

As shown in FIG. 7, each conduction path R11 in the semiconductor device A2 is longer than those in the semiconductor device A1. Thus, the element-to-element inductance L1 in the semiconductor device A2 is greater than that in the semiconductor device A1. In the example shown in FIG. 7, each conduction path R11 of the semiconductor device A2 is longer than those in the semiconductor device A1, as a result that each mounting portion 311a is longer in length in the second direction y from the portion bonded to a first semiconductor element 11 to the portion connected to the connecting portion 311b. As to the length of the conduction path R12, the semiconductor device A2 is the same (or substantially the same) as the semiconductor device A1. In the semiconductor device A2 of the example shown in FIG. 7, each conduction path R11 is longer than the conduction path R12. That is, in the semiconductor device A2, the element-to-element inductance L1 is greater than the element-to-terminal inductance L2 similarly to the semiconductor device A1.

The semiconductor device A2 configured as above obtains a greater element-to-element inductance L1 as compared with the semiconductor device A1. The semiconductor device A2 can therefore suppress the oscillation phenomenon during the parallel operation of the first semiconductor elements 11 more efficiently than the semiconductor device A1.

Similarly, as shown in FIG. 7, each conduction path R21 in the semiconductor device A2 is longer than those in the semiconductor device A1. Thus, the element-to-element inductance L3 in the semiconductor device A2 is greater than that in the semiconductor device A1. In the example shown in FIG. 7, each conduction path R21 of the semiconductor device A2 is longer than those in the semiconductor device A1, as a result that each mounting portion 331a is longer in length in the second direction y from the portion to bonded to a second semiconductor element 12 to the portion connected to the connecting portion 331b. As to the length of the conduction path R22, the semiconductor device A2 is the same (or substantially the same) as the semiconductor device A1. In the semiconductor device A2 of the example shown in FIG. 7, each conduction path R21 is longer than the conduction path R22. That is, in the semiconductor device A2, the element-to-element inductance L3 is greater than the element-to-terminal inductance L4 similarly to the semiconductor device A1.

The semiconductor device A2 configured as above obtains a greater element-to-element inductance L3 than the semiconductor device A1. The semiconductor device A2 can therefore suppress the oscillation phenomenon during the parallel operation of the second semiconductor elements 12 more efficiently than the semiconductor device A1.

### Second Variation of First Embodiment

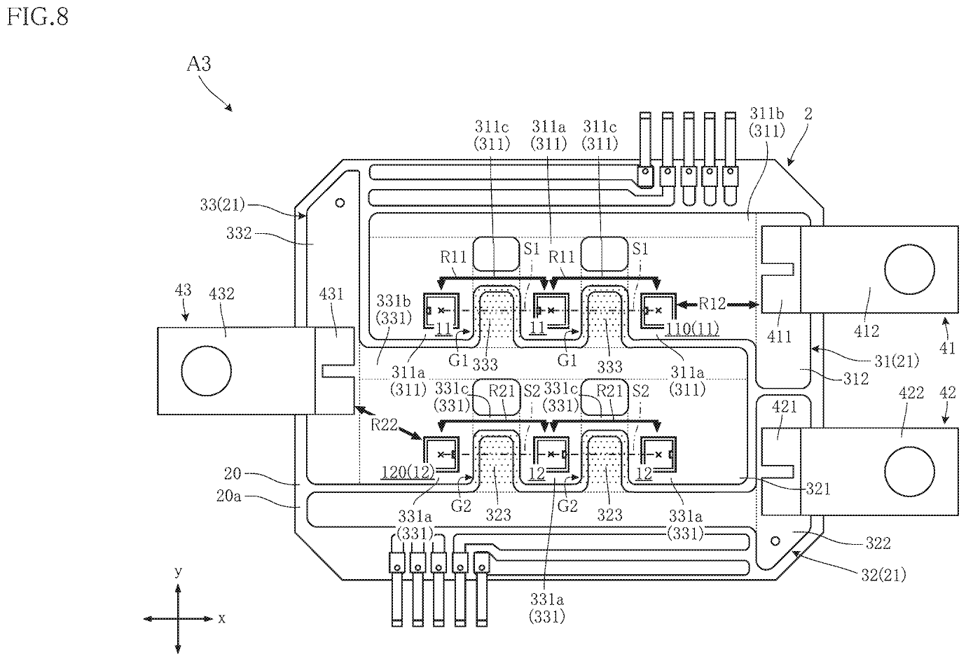

As shown in FIG. 8, the semiconductor device A3 differs from the semiconductor device A2 in that the pad portion 311 (the power wiring section 31) additionally includes a plurality of connecting portions 311c. Each connecting portion 311c electrically connects two mounting portions 311a adjacent in the first direction x. In the semiconductor device A3, two mounting portions 311a adjacent in the first direction x are electrically connected via the connecting portion 311b and a connecting portion 311c. With this configuration, each conduction path R11 is a path via a connecting portion 311c rather than a path via the connecting portion 311b. The resulting conduction paths R11 in the semiconductor device A3 are shorter than those in the semiconductor device A2, so that the element-to-element inductance L1 in the semiconductor device A3 is smaller than that in the semiconductor device A2. In the semiconductor device A3, the element-to-element inductance L1 is greater than the element-to-terminal inductance L2 similarly to the semiconductor device A1.

As shown in FIG. 8, the semiconductor device A3 also differs from the semiconductor device A2 in that the pad portion 331 (the power wiring section 33) additionally includes a plurality of connecting portions 331c. Each connecting portion 331c electrically connects two mounting portions 331a adjacent in the first direction x. In the semiconductor device A3, two mounting portions 331a adjacent in the first direction x are electrically connected via the connecting portion 331b and a connecting portion 331c. With this configuration, each conduction path R21 is a path via a connecting portion 311c rather than a path via the connecting portion 311b as shown in FIG. 8. The resulting conduction paths R21 in the semiconductor device A3 are shorter than those in the semiconductor device A2, so that the element-to-element inductance L3 in the semiconductor device A3 is smaller than that in the semiconductor device A2. In the semiconductor device A3 of the example shown in FIG. 8, the element-to-element inductance L3 is greater than the element-to-terminal inductance L4.

### Third Variation of First Embodiment

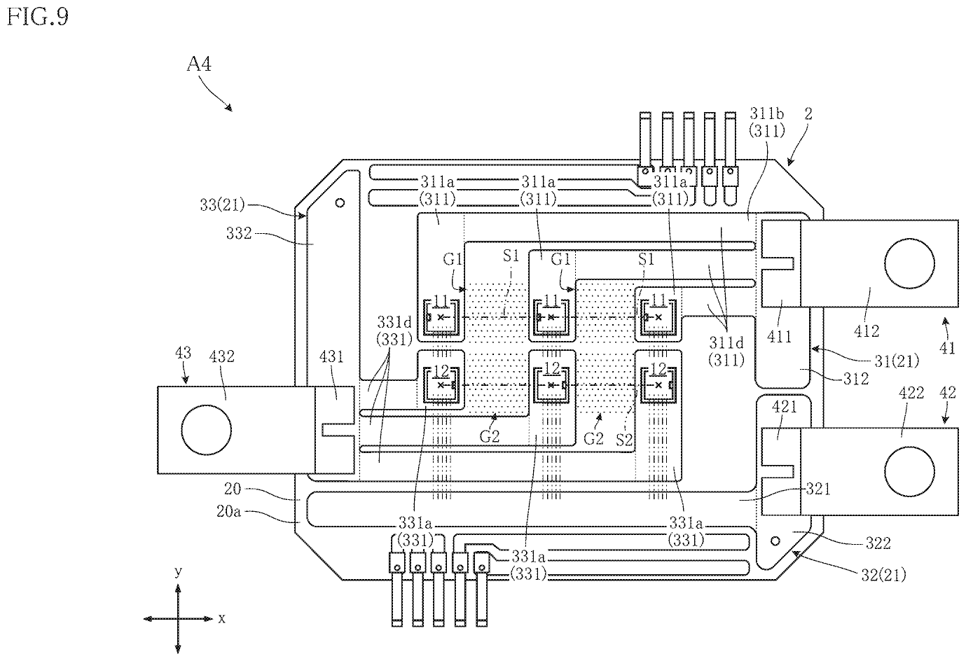

As shown in FIG. 9, the pad portion 311 (the power wiring section 31) of the semiconductor device A4 includes a plurality of strip-shaped portions 311d. Each strip-shaped portion 311d connects a mounting portion 311a and the pad portion 312. In plan view, the strip-shaped portions 311d extend in the first direction x and parallel (or substantially parallel) to each other in the second direction y.

In the semiconductor device A4 configured as above, the first electrodes 111 of two first semiconductor elements 11 adjacent in the first direction x are electrically connected to each other via the pad portion 312, so that the conduction path between the first electrodes 111 is longer than those in the semiconductor devices A1 to A3. Consequently, the element-to-element inductance L1 in the semiconductor device A4 is greater than that in the semiconductor devices A1 to A3. The semiconductor device A3 can therefore suppress the oscillation phenomenon during the parallel operation of the first semiconductor elements 11 more efficiently than the semiconductor devices A1 to A3.

As shown in FIG. 9, the pad portion 331 (the power wiring section 33) of the semiconductor device A4 includes a plurality of strip-shaped portions 331d. Each strip-shaped portion 331d connects a mounting portion 331a and the pad portion 332. In plan view, the strip-shaped portions 331d extend in the first direction x and parallel (or substantially parallel) to each other in the second direction y.

In the semiconductor device A4 configured as above, the fourth electrodes 121 of two second semiconductor elements 12 adjacent in the first direction x are electrically connected to each other via the pad portion 332, so that the conduction path between the fourth electrodes 121 is longer than those in the semiconductor devices A1 to A3. That is, the element-to-element inductance L3 in the semiconductor device A4 is greater than that in the semiconductor devices A1 to A3. The semiconductor device A4 can therefore suppress the oscillation phenomenon during the parallel operation of the second semiconductor elements 12 more efficiently than the semiconductor devices A1 to A3.

### Fourth Variation of First Embodiment

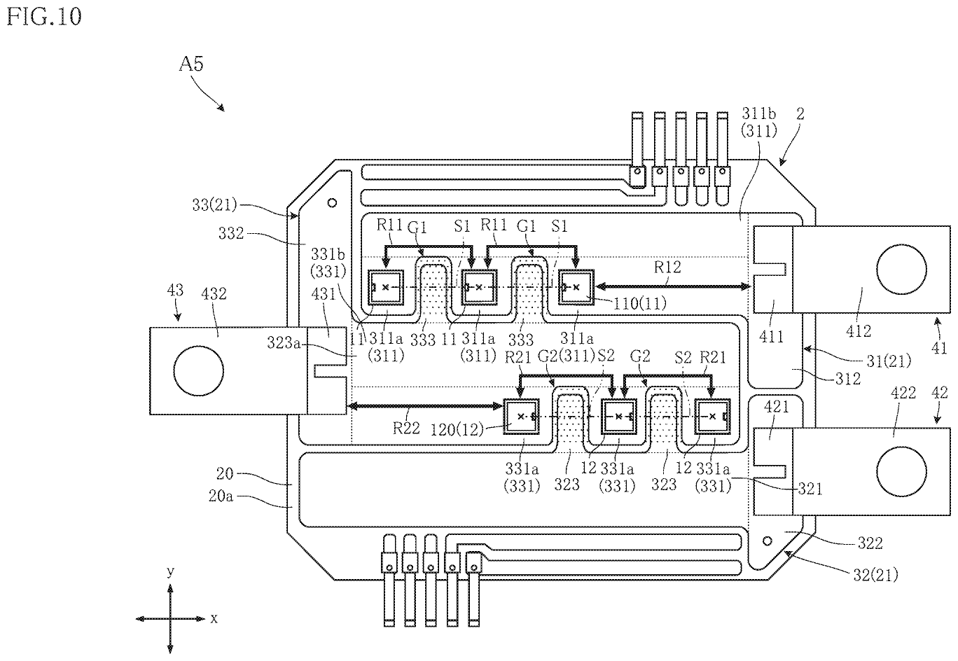

As shown in FIG. 10, each conduction path R11 in the semiconductor device A5 is shorter than those in the semiconductor device A1. That is, the element-to-element inductance L1 in the semiconductor device A5 is smaller than that in the semiconductor device A1. In addition, the conduction path R12 in the semiconductor device A5 is longer than that in the semiconductor device A1. That is, the element-to-terminal inductance L2 in the semiconductor device A5 is greater than that in the semiconductor device A1. In the example shown in FIG. 10, the first semiconductor elements 11 are offset to be away from the power terminal 41 in the first direction x to shorten each conduction path R11 and lengthen the conduction path R12. In the semiconductor device A5, each conduction path R11 is shorter than the conduction path R12. That is, in the semiconductor device A5, the element-to-element inductance L1 is smaller than the element-to-terminal inductance L2.

Similarly, as shown in FIG. 10, each conduction path R21 in the semiconductor device A5 is shorter than those in the semiconductor device A1. That is, the element-to-element inductance L3 in the semiconductor device A5 is smaller than that in the semiconductor device A1. In addition, the conduction path R22 in the semiconductor device A5 is longer than that in the semiconductor device A1. That is, the element-to-terminal inductance L4 in the semiconductor device A5 is greater than that in the semiconductor device A1. In the example shown in FIG. 10, the second semiconductor elements 12 are offset to be away from the power terminal 43 in the first direction x to shorten each conduction path R21 and lengthen the conduction path R22. In the semiconductor device A5, each conduction path R21 is shorter than the conduction path R22. That is, in the semiconductor device A5, the element-to-element inductance L3 is smaller than the element-to-terminal inductance L4.

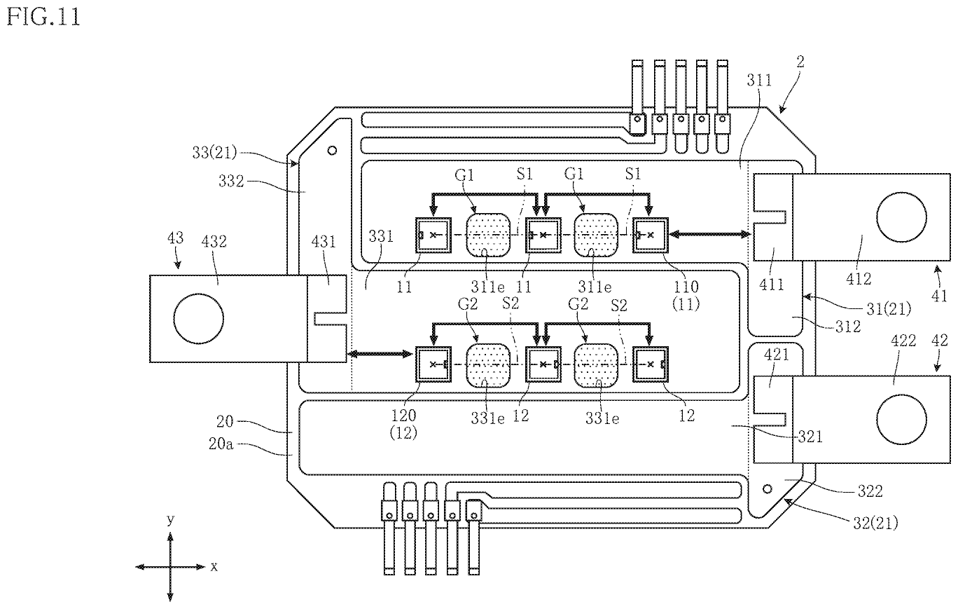

The semiconductor devices A1 to A5 are directed to the examples in which each first gap G1 is formed by a recess in the pad portion 311. In a different configuration as shown in FIG. 11, the pad portion 311 may have through-holes 311e each of which forms a first gap G1. The through-holes 311e penetrate the pad portion 311 (the obverse-surface metal layer 21) in the thickness direction z. Similarly, the semiconductor devices A1 to A5 are directed to the examples in which each second gap G2 is formed by a recess in the pad portion 331. In a different configuration as shown in FIG. 11, the pad portion 331 may have through-holes 331e each of which forms a second gap G2. The through-holes 331e penetrate the pad portion 331 (the obverse-surface metal layer 21) in the thickness direction z.

### Second Embodiment

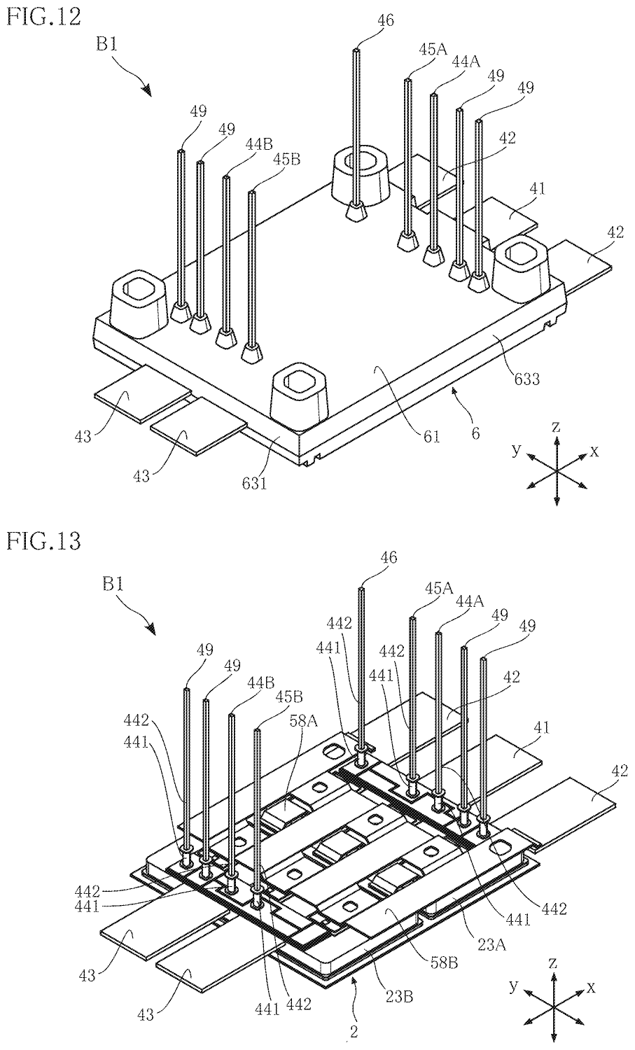

FIGS. 12 to 17 show a semiconductor device B1 according to a second embodiment. As shown in the figures, the semiconductor device B1 includes a plurality of first semiconductor elements a 11, plurality of second semiconductor elements 12, a supporting substrate 2, a plurality of terminals, a plurality of connecting members, and a sealing member 6. The plurality of terminals include a plurality of power terminals 41 to 43 and a plurality of signal terminals 44A, 44B, 45A, 45B, 46, and 49. The plurality of connecting members include a plurality of connecting members 531A, 531B, 541A, 541B, and 56 and a plurality of connecting members 58A and 58B.

The supporting substrate 2 of the semiconductor device B1 includes an insulating substrate 20, an obverse-surface metal layer 21, a reverse-surface metal layer 22, a pair of substrates 23A and 23B, and a pair of signal conductive substrates 24A and 24B. The supporting substrate 2 is configured by stacking the pair of conductive substrates 23A and 23B and the pair of signal substrates 24A and 24B on a DBC substrate (or a DBA substrate). As in the semiconductor device A1, the DBC substrate (or the DBA substrate) is composed of the insulating substrate 20, the pair of obverse-surface metal layers 21A and 21B, and the reverse-surface metal layer 22.

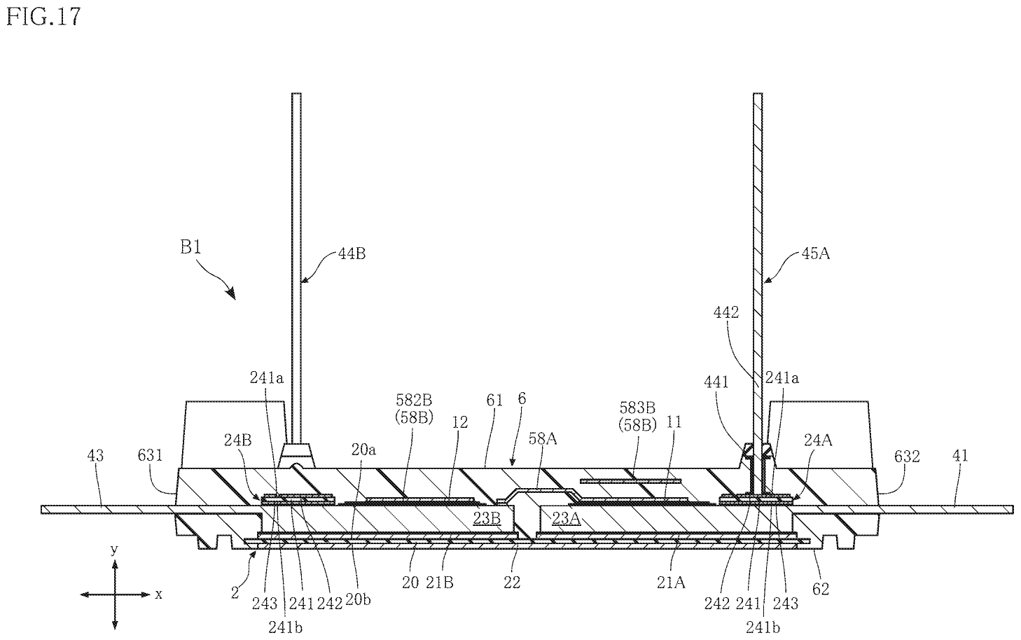

As shown in FIG. 17, the pair of obverse-surface metal layers 21A and 21B are formed on the obverse surface 20a of the insulating substrate 20. The obverse-surface metal layers 21A and 21B are spaced apart in the first direction x. The conductive substrate 23A is bonded to the obverse-surface metal layer 21A, and the conductive substrate 23B is bonded to the obverse-surface metal layer 21B. In plan view, the obverse-surface metal layers 21A and 21B are rectangular, for example. In a different configuration, the obverse-surface metal layers 21A and 21B may be respectively similar to the conductive substrates 23A and 23B as to the shapes defined by the respective outer edges in plan view.

Each of the conductive substrates 23A and 23B is made of metal. Examples of the metal include copper and a copper alloy or aluminum and an aluminum alloy.

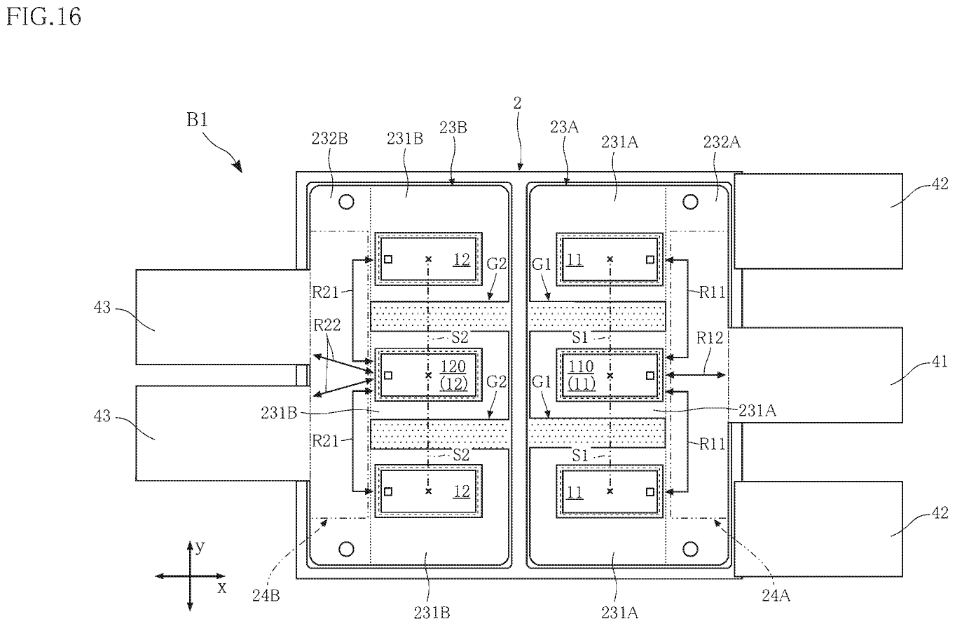

As shown in FIG. 17, the conductive substrate 23A is disposed on the obverse-surface metal layer 21A. As shown in FIG. 17, the conductive substrate 23A receives a plurality of first semiconductor elements 11 mounted thereon. As shown in FIG. 16, in the semiconductor device B1, the e first semiconductor elements 11 are arranged along the second direction y on the conductive substrate 23A. The conductive substrate 23A faces the first-element reverse surface 11b of each first semiconductor element 11. The first electrodes 111 (drains) of the first semiconductor elements 11 are electrically bonded to the conductive substrate 23A. The first electrodes 111 of the first semiconductor elements 11 are electrically connected to each other via the conductive substrate 23A. As shown in FIG. 16, the conductive substrate 23A is disposed to avoid being located on a portion of each first line segment S1 in plan view. In one example, the conductive substrate 23A is disposed to avoid being located on at least 15% and at most 90% (preferably at least 25% and at most 90%) of each first line segment S1 in plan view. In the present embodiment, the conductive substrate 23A is an example of a “first conductor”.

The conductive substrate 23A includes a plurality of mounting portions 231A and a connecting portion 232A.

As shown in FIG. 16, one first semiconductor element 11 is mounted on each mounting portion 231A, and the first electrode 111 (drain) of the first semiconductor element 11 is bonded to the mounting portion 231A. In plan view, each mounting portion 231A is rectangular, for example. Each mounting portion 231A includes a portion overlapping with the relevant first semiconductor element 11 and a portion extending therebeyond in plan view. As shown in FIG. 16, the mounting portions 231A are spaced apart from each other in the second direction y and parallel (or substantially parallel) to each other in the second direction y. Each mounting portion 231A is connected to the connecting portion 232A at the end in the first sense of the first direction x. Hence, the mounting portions 231A are electrically connected to each other via the connecting portion 232A. In the present embodiment, each mounting portion 231a is an example of a “first mounting portion”.

As shown in FIG. 16, the mounting portions 231A are arranged along the second direction y with a first gap G1 interposed between any two mounting portions 231A adjacent in the second direction y. For the convenience of description, each first gap G1 is indicated by a doted area in FIG. 16. Each first gap G1 intersects a first line segment S1. Each first gap G1 is provided by, for example, forming a recess in the edge of the conductive substrate 23A in the second sense of the first direction x (the edge remote from the power wiring section 41).

As shown in FIG. 16, the connecting portion 232A is connected to the mounting portions 231A. For example, the connecting portion 232A has a rectangular shape extending in the second direction y in plan view. As shown in FIG. 16, the connecting portion 232A is located on the side opposite to the second semiconductor elements 12 in the first direction x with respect to the mounting portions 231A. Also, the connecting portion 232A is located on the side opposite to the second semiconductor elements 12 in the first direction x with respect to the first line segments S1. In plan view, the connecting portion 232A overlaps with the signal substrate 24A. In the present embodiment, the connecting portion 232A is an example of a “first connecting portion”.

As shown in FIG. 17, the conductive substrate 23B is disposed on the obverse-surface metal layer 21B. As shown in FIG. 17, the conductive substrate 23B receives a plurality of second semiconductor elements 12 mounted thereon. As shown in FIG. 16, in the semiconductor device B1, the second semiconductor elements 12 are arranged along the second direction y on the conductive substrate 23B. The conductive substrate 23B faces the second-element reverse surface 12b of each second semiconductor element 12. The fourth electrodes 121 (drains) of the second semiconductor elements 12 are electrically bonded to the conductive substrate 23B. The fourth electrodes 121 of the second semiconductor elements 12 are electrically connected to each other via the conductive substrate 23B. As shown in FIG. 16, the conductive substrate 23B is disposed to avoid being located on a portion of each second line segment S2 in plan view. In one example, the conductive substrate 23B is disposed to avoid being located on at least 15% and at most 90% (preferably at least 25% and at most 90%) of each second line segment S2 in plan view. The connecting members 58A are bonded to the conductive substrate 23B to electrically connect the conductive substrate 23B to the second electrodes 112 (sources) of the first semiconductor element 11 via the connecting members 58A. In the present embodiment, the conductive substrate 23B is an example of the “second conductor”.

The conductive substrate 23B includes a plurality of mounting portions 231B and a connecting portion 232B.

As shown in FIG. 16, one second semiconductor element 12 is mounted on each mounting portion 231B, and the fourth electrode 121 (drain) of the second semiconductor element 12 is bonded to the mounting portion 231B. In plan view, each mounting portion 231B is rectangular, for example. Each mounting portion 231B includes a portion overlapping with the relevant second semiconductor element 12 and a portion extending therebeyond in plan view. The mounting portions 231B are spaced apart from each other in the second direction y and parallel (or substantially parallel) to each other in the second direction y. Each mounting portion 231B is connected to the connecting portion 232B at the end in the first sense of the first direction x. Hence, the mounting portions 231B are electrically connected to each other via the connecting portion 232B. In the present embodiment, each mounting portion 231B is an example of a “second mounting portion”.

As shown in FIG. 16, the mounting portions 231B are arranged along the second direction y with a second gap G2 interposed between any two mounting portions 231B adjacent in the second direction y. For the convenience of description, each second gap G2 is indicated by a doted area in FIG. 16. Each second gap G2 intersects a second line segment S2. Each second gap G2 is provided by, for example, forming a recess in the edge of conductive substrate 23B in the first sense of the first direction x (the edge remoted from the power wiring sections 43).

As shown in FIG. 16, the connecting portion 232B is connected to the mounting portions 231B. For example, the connecting portion 232B has a rectangular shape extending in the second direction y in plan view. As shown in FIG. 16, the connecting portion 232B is located on the side opposite to the first semiconductor elements 11 in the first direction x with respect to the mounting portions 231B. Also, the connecting portion 232B is located on the side opposite to the first semiconductor elements 11 in the first direction x with respect to the second line segments S2. In plan view, the connecting portion 232B overlaps with the signal substrate 24B. In the present embodiment, the connecting portion 232B is an example of a “second connecting portion”.

The signal substrates 24A and 24B support the signal terminals 44A, 44B, 45A, 45B, 46, and 49. As shown in FIG. 17, each of the signal substrates 24A and 24B is located between the conductive substrate 23A or 23B and the relevant ones of the signal terminals 44A, 44B, 45A, 45B, 46, or 49. Each of the signal substrates 24A and 24B is made of a DBC substrate, for example. In a different configuration, each of the signal substrates 24A and 24B may be made of a DBA substrate, for example. In a different configuration, each of the signal substrates 24A and 24B may be made of a printed board, instead of a DBC or DBA substrate.

As shown in FIG. 17, the signal substrate 24A is disposed on the conductive substrate 23A. The signal substrates 24A supports the signal terminals 44A, 45A, 46, and 49. The signal substrate 24A is bonded to the conductive substrate 23A via a bonding material. The bonding material can be either conductive or insulative, and solder is one example. As shown in FIG. 17, the signal substrate 24B is disposed on the conductive substrate 23B. The signal substrate 24B supports the signal terminals 44B, 45B, and 49. The signal substrate 24B is bonded to the conductive substrate 23B via a bonding material. The bonding material may be conductive or insulative, and solder is one example.

As shown in FIG. 17, each of the signal substrates 24A and 24B includes an insulating layer 241, an obverse-surface metal layer 242 and a reverse-surface metal layer 243. Unless otherwise specifically noted, the insulating layer 241, the obverse-surface metal layer 242, and the reverse-surface metal layer 243 described below are similarly configured for both the signal substrates 24A and 24B.

The insulating layer 241 is made of a ceramic material, for example. The ceramic material may be AlN, SiN, or Al₂O₃. In plan view, the insulating layer 241 is rectangular, for example. As shown in FIG. 17, the insulating layer 241 has an obverse surface 241a and a reverse surface 241b. The obverse surface 241a and the reverse surface 241b are spaced apart in the thickness direction z. The obverse surface 241a faces upward and the reverse surface 241b faces downward in the thickness direction z. Each of the obverse surface 241a and the reverse surface 241b is flat (or substantially flat).

As shown in FIG. 17, the reverse-surface metal layer 243 is formed on the reverse surface 241b of the insulating layer 241. The reverse-surface metal layer 243 of the signal substrate 24A is bonded to the conductive substrate 23A via a bonding material. The reverse-surface metal layer 243 of the signal substrate 24B is bonded to the conductive substrate 23B via a bonding material. The reverse-surface metal layer 243 is made of Cu or a Cu alloy, for example. The material of the reverse-surface metal layer 243 may be A1 or a A1 alloy, instead of Cu or a Cu alloy.

As shown in FIG. 17, the obverse-surface metal layer 242 is formed on the obverse surface 241a of the insulating layer 241. Each of the signal terminals 44A, 44B, 45A, 45B, 46, and 49 is disposed to stand on the obverse-surface metal layer 242 of the signal substrate 24A or 24B. The obverse-surface metal layer 242 is made of Cu or a Cu alloy, for example. The material of the obverse-surface metal layer 242 may be A1 or a A1 alloy, instead of Cu or a Cu alloy.

The obverse-surface metal layer 242 of the signal substrate 24A includes a plurality of signal wiring sections 34A, 35A, 36, and 39. The obverse-surface metal layer 242 of the signal substrate 24B includes a plurality of signal wiring sections 34B, 35B, and 39.

The connecting member 56 is bonded to the signal wiring section 36, so that the signal wiring section 36 is electrically connected to the conductive substrate 23A via the connecting member 56. The conductive substrate 23A is electrically connected to the first electrodes 111 (drains) of the first semiconductor elements 11. Hence, the signal wiring section 36 is electrically connected to the first electrodes 111 (drains) of the first semiconductor elements 11.

The power terminal 41 is integrally formed with the conductive substrate 23A. In a different configuration, the power terminal 41 may be a separate component bonded to the conductive substrate 23A. The power terminal 41 is connected to the connecting portion 232A. The power terminal 41 is shorter in length in the thickness direction z than the conductive substrate 23A. The power terminal 41 extends from the conductive substrate 23A in the first sense of the first direction x. The first sense of the first direction x is the direction toward the side opposite to the conductive substrate 23B with respect to conductive substrate 23A. The power terminal 41 protrudes from the resin side surface 632. The power terminal 41 is electrically connected to the first electrodes 111 (drains) of the first semiconductor elements 11 via the conductive substrate 23A.

The two power terminals 42 are spaced apart from the conductive substrate 23A. The two power terminals 42 are located opposite to each other in the second direction y with the power terminal 41 located between them. The two power terminals 42 are located in the first sense of first direction x from the conductive substrate 23A. The first sense of the first direction x is the direction toward the power terminal 41 with respect to conductive substrate 23A. The two power terminals 42 protrude from the resin side surface 632. The connecting member 58B is bonded to the two power terminals 42. The two power terminals 42 are electrically connected to the fifth electrodes 122 (sources) of the second semiconductor elements 12 via the connecting member 58B.

The two power terminals 43 are integrally formed with the conductive substrate 23B. In a different configuration, the power terminals 43 may be separate components bonded to the conductive substrate 23B. The two power terminals 43 are connected to the connecting portion 232B. The two power terminals 43 are shorter in length in the thickness direction z than the conductive substrate 23B. The power terminals 43 extend from the conductive substrate 23B in the second sense of the first direction x. The second sense of the first direction x is the direction away from the conductive substrate 23A with respect to conductive substrate 23B. The two power terminals 43 protrude from the resin side surface 631. Each of the two power terminals 43 is electrically connected to the second electrodes 112 (sources) of the first semiconductor elements 11 and the fourth electrodes 121 (drains) of the second semiconductor elements 12 via the conductive substrate 23B.

The signal terminals 44A, 44B, 45A, 45B, 46, and 49 protrude from the resin obverse surface 61. The signal terminals 44A, 44B, 45A, 45B, 46, and 49 may be press-fit terminals. Each of the signal terminals 44A, 44B, 45A, 45B, 46, and 49 includes a holder 441 and a metal pin 442.

The holder 441 is made of a conductive material. The holder 441 has a tubular shape. The holder 441 of the signal terminal 44A is bonded to the signal wiring section 34A, and the holder 441 of the signal terminal 44B is bonded to the signal wiring section 34B. The holder 441 of the signal terminal 45A is bonded to the signal wiring section 35A, the holder 441 of the signal terminal 45B is bonded to the signal wiring section 35B, and the holder 441 of the signal terminal 46 is bonded to the signal wiring section 36. The metal pin 442 is press-fitted into the holder 441 to extend in the thickness direction z. The metal pin 442 protrudes upward in the thickness direction z from the resin obverse surface 61 of the sealing member 6, with a portion thereof exposed from the sealing member 6.

The signal terminal 46 is disposed to stand on the signal wiring section 36. The signal terminal 46 is electrically connected to the signal wiring section 36. Since the signal wiring section 36 is electrically connected to the first electrodes 111 of the first semiconductor elements 11, the signal terminal 46 is electrically connected to the first electrodes 111 of the first semiconductor elements 11.

The signal terminal 49 is disposed to stand on the signal wiring section 39. The signal terminals 49 are not electrically connected to any of the first semiconductor elements 11 and the second semiconductor elements 12. The signal terminals 49 are no-connection terminals.

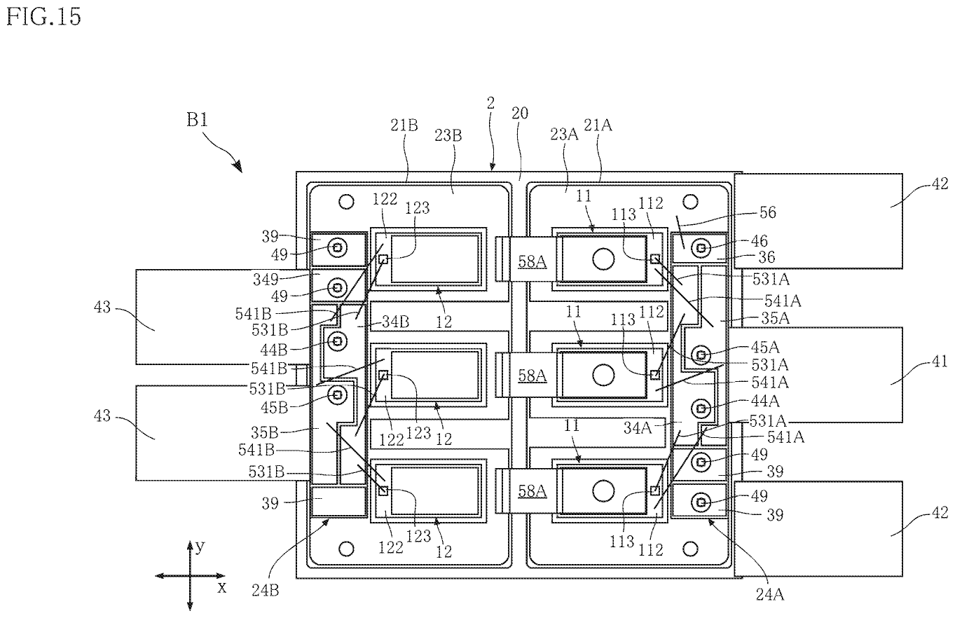

The connecting member 56 may be a bonding wire, for example. The material of the bonding wire may be any of gold, copper, or aluminum. As shown in FIG. 15, the connecting member 56 is bonded to the signal wiring section 36 and the conductive substrate 23A to provide electrical connection between them.

The connecting members 58A and 58B, together with the supporting substrate 2, form paths for the main circuit currents switched on and off by the first semiconductor elements 11 and the second semiconductor elements 12. Each of the connecting members 58A and 58B is a plate-like member made of metal. Examples of the metal include Cu and a Cu alloy. The connecting members 58A and 58B have a portion that is bent.

Each connecting member 58A is bonded to the second electrode 112 (source) of a first semiconductor element 11 and also to the conductive substrate 23B to electrically connect the second electrode 112 of the first semiconductor element 11 and the conductive substrate 23B. To bond of each connecting member 58A to the second electrode 112 of a first semiconductor element 11 and to the conductive substrate 23B, a conductive bonding material (e.g., solder, metal paste, and sintered metal) may be used. As shown in FIG. 15, each connecting member 58A has a strip shape extending in the first direction x in plan view.

In the illustrated example, the numbers of the connecting members 58A included is three, which is equal to the number of the first semiconductor elements 11 included. In a different configuration, the number of the connecting members 58A may differ from the number of the first semiconductor elements 11. For example, a single connecting member 58A may be provided for a plurality of first semiconductor elements 11.

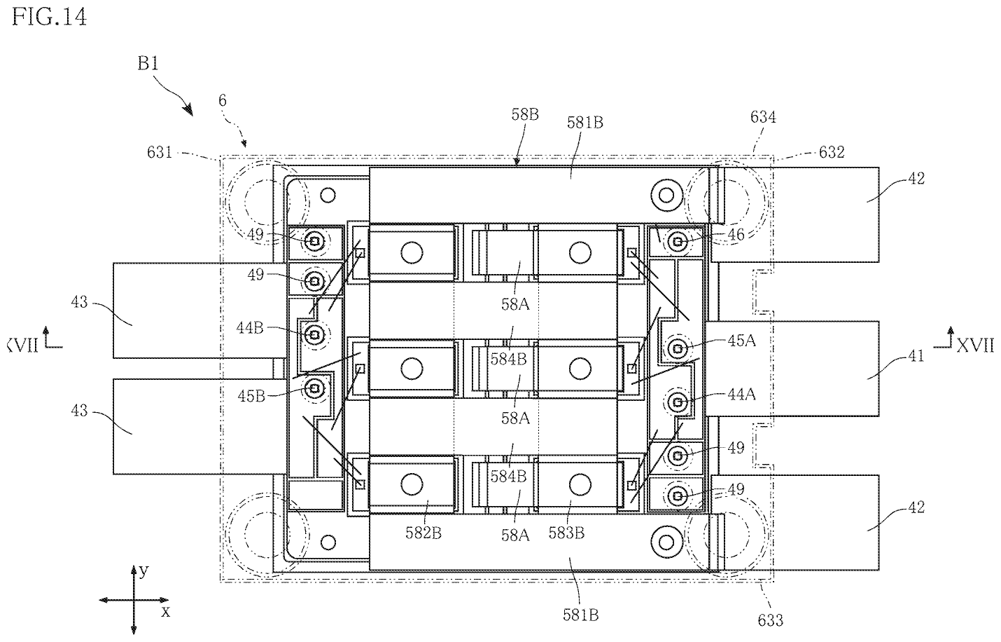

The connecting member 58B electrically connects the fifth electrodes 122 (sources) of the second semiconductor elements 12 to the power terminals 42. As shown in FIG. 14, the connecting member 58B includes a pair of first wiring sections 581B, a second wiring section 582B, a third wiring section 583B, and a plurality of fourth wiring sections 584B.

One of the first wiring sections 581B is connected to one of the power terminals 42, and the other first wiring section 581B is connected to the other power terminal 42. The first wiring sections 581B and the power terminals 42 are connected using a conductive bonding material (such as solder, metal paste, or sintered metal). As shown in FIG. 14, each first wiring section 581B has a strip shape extending in the first direction x in plan view. The first wiring sections 581B are spaced apart in the second direction y and parallel (or substantially parallel) to each other.

As shown in FIG. 14, the second wiring section 582B is connected to both of the first wiring sections 581B. The second wiring section 582B is a strip-shaped portion extending in the second direction y in plan view. As can be seen from FIGS. 14 and 17, the second wiring section 582B overlaps with the second semiconductor elements 12 in plan view. As shown in FIG. 17, the second wiring section 582B is connected to the fifth electrodes 122 (sources) of the second semiconductor elements 12. The portions of the second wiring section 582B overlapping with the second semiconductor elements 12 in plan view protrude downward in the thickness direction z relative to the rest of the second wiring section 582B. The second wiring section 582B is bonded to the fifth electrodes 122 of the second semiconductor elements 12 at these portions protruding downward. The second wiring section 582B and each fifth electrode 122 may be bonded using a conductive bonding material (e.g., solder, metal paste, or sintered metal).

As shown in FIG. 14, the third wiring section 583B is connected to both of the first wiring sections 581B. The third wiring section 583B is a strip-shaped portion extending in the second direction y in plan view. The third wiring section 583B is spaced apart from the second wiring section 582B in the first direction x. The third wiring section 583B extends parallel (or substantially parallel) to the second wiring section 582B. As can be seen from FIGS. 14 and 17, the third wiring section 583B overlaps with the first semiconductor elements 11 in plan view. The portions of the third wiring 583B overlapping with section the first semiconductor elements 11 in plan view protrude upward in the thickness direction z relative to the rest of the third wiring section 583B. These portions protruding upward provide spaces above the first semiconductor elements 11, so that the third wiring section 583B can avoid touching the connecting members 58A bonded to the first semiconductor elements 11.

As shown in FIG. 14, each fourth wiring section 584B is connected to both of the second wiring section 582B and the third wiring section 583B. Each fourth wiring section 584B is a strip-shaped portion extending in the first direction x in plan view. The fourth wiring sections 584B are spaced apart from each other in the second direction y and parallel (or substantially parallel) to each other in plan view. One end of each fourth wiring section 584B in the first direction x overlaps with a portion of the third wiring section 583B located between two first semiconductor elements 11 adjacent in the second direction y in plan view. The other end of each fourth wiring section 584B in the first direction x overlaps with a portion of the second wiring section 582B located between two second semiconductor elements 12 adjacent in the second direction y.

In the semiconductor device B1, a conduction path R11 between the first electrodes 111 (drains) of two first semiconductor elements 11 adjacent in the second direction y (see FIG. 16) is longer than a conduction path R12 between the first electrode 111 (drain) of the first proximity element 110 and the power terminal 41 (P terminal) (see FIG. 16). Consequently, the element-to-element inductance L1, which is the inductance of the conduction path R11, is greater than the element-to-terminal inductance L2, which is the inductance of the conduction path R12.

Similarly, in the semiconductor device B1, a conduction path R21 between the fourth electrodes 121 (drains) of two second semiconductor elements 12 adjacent in the second direction y (see FIG. 16) is longer than a conduction path R22 between the fourth electrode 121 (drain) of the second proximity element 120 and each power terminal 43 (OUT terminal) (see FIG. 16). Consequently, the element-to-element inductance L3, which is t inductance of the conduction path R21, is greater than the element-to-terminal inductance L4, which is the inductance of the conduction path R22.

The operation and effect of the semiconductor device B1 are as follows.

Similarly to the semiconductor device A1, the semiconductor device B1 includes the f first semiconductor elements 11, and the first semiconductor elements 11 are electrically connected in parallel. The semiconductor device B1 includes the conductive substrate 23A as a first conductor. As viewed in the thickness direction z, the conductive substrate 23A is disposed to avoid being located on a portion of each first line segment S1. This configuration increases the element-to-element inductance L1 as compared with a configuration in which the conductive substrate 23A is without the first disposed avoiding line S1 segments (hereinafter, a “third comparative configuration”). In the third comparative configuration, a linear conduction path is formed between the first electrodes 111 (drains) of the first semiconductor elements 11 as in JP-A-2016-225493. The semiconductor device B1 can therefore suppress the oscillation phenomenon during the parallel operation of the first semiconductor elements 11 more efficiently than the third comparative configuration.

In the semiconductor device B1, the conductive substrate 23A as a first conductor is disposed to avoid being located on 15% or more of each first line segment S1. Similarly to the semiconductor device A1, the semiconductor device B1 can obtain the element-to-element inductance L1 that is appropriate for suppressing the oscillation phenomenon during the parallel operation of the first semiconductor elements 11. Notably, in addition, the conductive substrate 23A is disposed to avoid being located on at most 90% of each first line segment S1 as viewed in the thickness direction z. Similarly to the semiconductor device A1, the semiconductor device B1 of this configuration can reduce the possibility that a first semiconductor element 11 is placed to extend out of a relevant mounting portion 231A. This can consequently prevent reducing the reduced bonding strength of each first semiconductor element 11 and reducing the bonding area between each first electrode 111 and a relevant mounting portion 231a. In view of the above, with the conductive substrate 23A as a first conductor disposed to avoid being located on at least 15% and at most 90% of each first line segment S1, the semiconductor device B1 can obtain an appropriate element-to-element inductance L1 and ensure that the first semiconductor elements 11 are appropriately bonded to the mounting portions 231A.

In the semiconductor device B1, the conductive substrate 23A includes the plurality of mounting portions 231A for mounting the plurality of first semiconductor elements 11. The mounting portions 231A are arranged along the second direction y with a first gap G1 interposed between any two mounting portions 231A adjacent in the second direction y. As viewed in the thickness direction z, the first gap G1 intersects the first line segment S1. With this configuration, the conductive substrate 23A is shaped to avoid a portion of each first line segment S1. Similarly to the semiconductor device A1, the semiconductor device B1 can therefore increase the element-to-element inductance L1 as compared with the third comparative configuration described above.

Similarly to the semiconductor device A1, the semiconductor device B1 includes two or more second semiconductor elements 12, and the two or more second semiconductor elements 12 are electrically connected in parallel. The semiconductor device B1 includes the conductive substrate 23B as a second conductor. As viewed in the thickness direction z, the conductive substrate 23B is disposed to avoid being located on a portion of each second line segment S2. This configuration increases the element-to-element inductance L3 as compared with a configuration in which the conductive substrate 23B is disposed without avoiding the second line segments S2 (hereinafter, a “fourth comparative configuration”). In the fourth comparative configuration, a linear conduction path is formed between the fourth electrodes 121 (drains) of the second semiconductor elements 12 as in JP-A-2016-225493. The semiconductor device B1 can therefore suppress the oscillation phenomenon during the parallel operation of the two or more second semiconductor elements 12 more efficiently than the fourth comparative configuration.

In the semiconductor device B1, the conductive substrate 23B as a second conductor is disposed to avoid being located on 15% or more of each second line segment S2. Similarly to the semiconductor device A1, the semiconductor device B1 of this configuration can obtain the element-to-element inductance L3 that is appropriate for suppressing the oscillation phenomenon during the parallel operation of the second semiconductor elements 12. Notably, in addition, the conductive substrate 23B is disposed to avoid being located on at most 90% of each second line segment S2 as viewed in the thickness direction z. Similarly to the semiconductor device A1, the semiconductor device B1 of this configuration can reduce the possibility that a second semiconductor element 12 is placed to extend out of a relevant mounting portion 231B. This can consequently prevent reducing the bonding strength of each second semiconductor element 12 and reducing the area between each fourth electrode 121 and a relevant mounting portion 231B. In view of the above, with the conductive substrate 23B as a second conductor disposed to avoid being located on at least 15% and at most 90% of each second line segment S2, the semiconductor device B1 can obtain an appropriate element-to-element inductance L3 and ensure that the second semiconductor elements 12 are appropriately bonded to the mounting portions 231B.

In the semiconductor device B1, the conductive substrate 23B includes the plurality of mounting portions 231B for mounting the plurality of second semiconductor elements 12. The mounting portions 231B are arranged along the second direction y with a second gap G2 interposed between any two mounting portions 231B adjacent in the second direction y. The second gap G2 intersects the second line segment S2 as viewed in the thickness direction z. With this configuration, the conductive substrate 23B is shaped to avoid a portion of each second line segment S2. The semiconductor device B1 can therefore increase the element-to-element inductance L3 as compared with the fourth comparative configuration described above.

### Variations of Second Embodiment

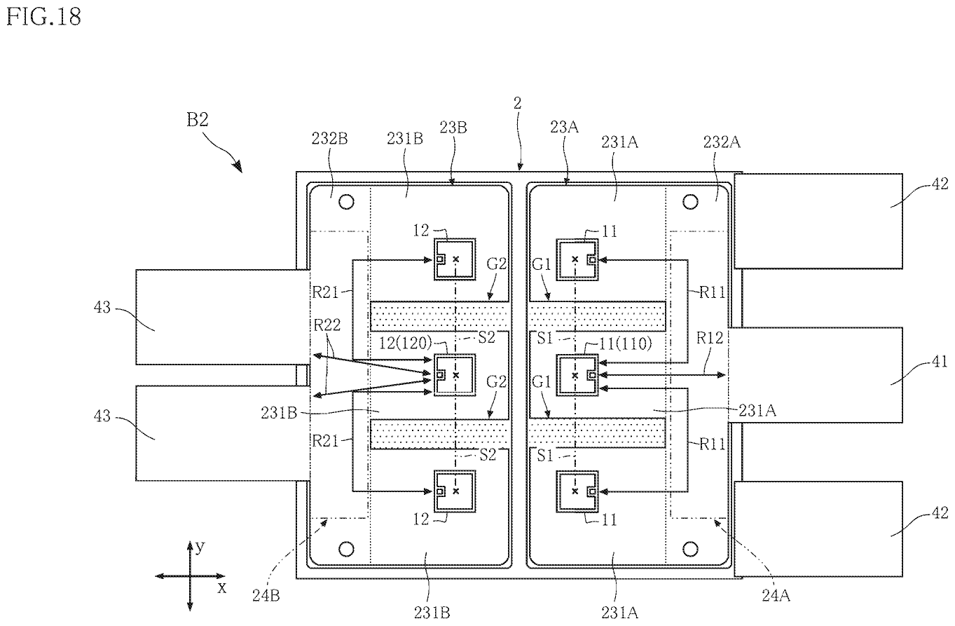

Next, variations of the semiconductor device B1 according to the second embodiment will be described with reference to FIGS. 18 to 21. FIGS. 18 to 21 show semiconductor devices B2 to B5 according to first to fourth variations of the second embodiment.

First, the features of the semiconductor devices B2 to B5 that are common with the semiconductor device B1 and also common with each other will be described.

The semiconductor devices B2 to B5 have the following features in common with the semiconductor device B1. First, as shown in FIGS. 18 to 21, the conductive substrate 23A is disposed to avoid being located on a portion of each first line segment S1 as viewed in the thickness direction z. Second, as shown in FIGS. 18 to 21, the conductive substrate 23B is disposed to avoid being located on a portion of each second line segment S2 as viewed in the thickness direction z. Third, as shown in FIGS. 18 to 21, two mounting portions 231A are adjacent in the second direction y across a first gap G1, and the first gap G1 intersects the first line segment S1 as viewed in the thickness direction z. Fourth, as shown in FIGS. 18 to 21, two mounting portions 231B are adjacent in the second direction y across a second gap G2, and the second gap G2 intersects the second line segment S2 as viewed in the thickness direction z.

With the first common feature described above, each of the semiconductor devices B2 to B5 can increase the element-to-element inductance L1 compared as with the third comparative configuration described above and similarly to the semiconductor device B1. That is, similarly to the semiconductor device B1, each of the semiconductor devices B2 to B5 outperforms the third comparative configuration in suppressing the oscillation phenomenon during the parallel operation of the first semiconductor elements 11. With the second common feature described above, each of the semiconductor devices B2 to B5 can increase the element-to-element inductance L3 as compared with the fourth comparative configuration described above and similarly to the semiconductor device B1. That is, similarly to the semiconductor device B1, each of the semiconductor devices B2 to B5 outperforms the fourth comparative configuration in suppressing the oscillation phenomenon during the parallel operation of the second semiconductor elements 12.

Next, the following sequentially describes the semiconductor devices B2 to B5 according to the first to fourth variations of the second embodiment, respectively.

### First Variation of Second Embodiment

As shown in FIG. 18, each conduction path R11 in the semiconductor device B2 is longer than those in the semiconductor device B1. That is, the element-to-element inductance L1 in the semiconductor device B2 is greater than that in the semiconductor device B1. In addition, the conduction path R12 in the semiconductor device B2 is longer than that in the semiconductor device B1. In the example shown in FIG. 18, each conduction path R11 of the semiconductor device B2 is longer than those in the semiconductor device B1, as a result that each first semiconductor element 11 is smaller in plan view and is offset on the mounting portion 231A away from the power terminal 41 in the first direction x. In the example shown in FIG. 18, the semiconductor device B2 is similar to the semiconductor device B1 in that each conduction path R11 is longer than the conduction path R12. That is, in the semiconductor device B2, the element-to-element inductance L1 is greater than the element-to-terminal inductance L2.

The semiconductor device B2 configured as above obtains a greater element-to-element inductance L1 than the semiconductor device B1. The semiconductor device B2 can therefore suppress the oscillation phenomenon during the parallel operation of the first semiconductor elements 11 more efficiently than the semiconductor device B1.

Similarly, as shown in FIG. 18, each conduction path R21 in the semiconductor device B2 is longer than those in the semiconductor device B1. That is, the element-to-element inductance L3 in the semiconductor device B2 is greater than that in the semiconductor device B1. In addition, the conduction path R22 in the semiconductor device B2 is longer than that in the semiconductor device B1. In the example shown in FIG. 18, each conduction path R21 of the semiconductor device B2 is longer than those in the semiconductor device B1, as a result that each second semiconductor element 12 is smaller in plan view and is offset on the mounting portion 231B away from the power terminals 43 in the first direction x. In the example shown in FIG. 18, the semiconductor device B2 is similar to the semiconductor device B1 in that each conduction path R21 is longer than the conduction path R22. That is, in the semiconductor device B2, the element-to-element inductance L3 is greater than the element-to-terminal inductance L4.

The semiconductor device B2 configured as above obtains a greater element-to-element inductance L3 as compared with the semiconductor device B1. The semiconductor device B2 can therefore suppress the oscillation phenomenon during the parallel operation of the second semiconductor elements 12 more efficiently than the semiconductor device B1.

### Second Variation of Second Embodiment

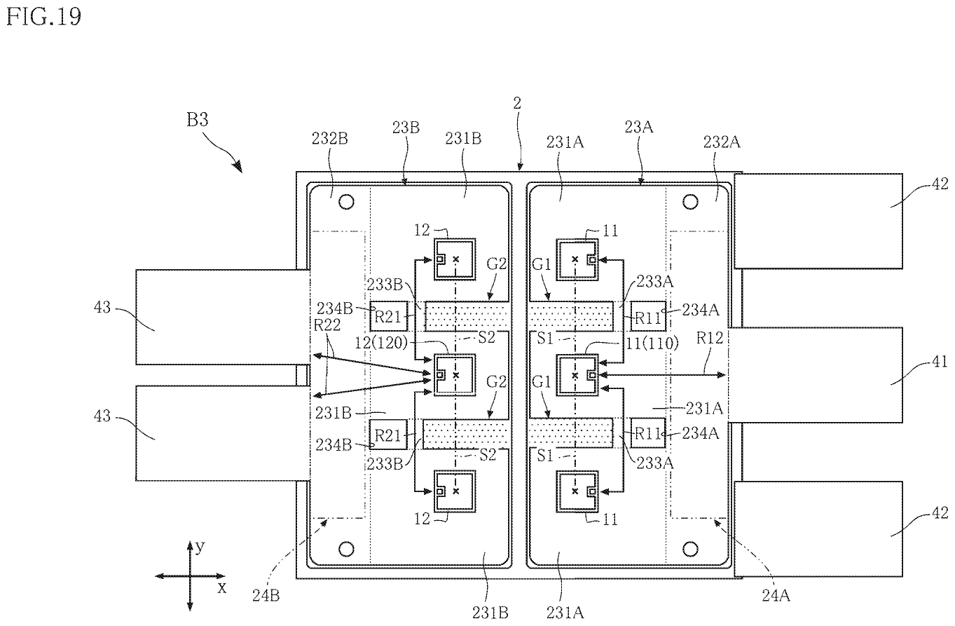

As shown in FIG. 19, the semiconductor device B3 differs from the semiconductor device B2 in that the conductive substrate 23A additionally includes a plurality of connecting portions 233A. Each connecting portion 233A electrically connects two mounting portions 231a adjacent in the second direction y. In the semiconductor device B3, two mounting portions 231A adjacent in the second direction y are electrically connected via the connecting portion 232A and a connecting portion 233A. With this structure, each conduction path R11 is a path via a connecting portion 233A rather than a path via the connecting portion 232A as shown in FIG. 19. As a result, each conduction path R11 in the semiconductor device B3 is shorter than those in the semiconductor device B2, so that the element-to-element inductance L1 in the semiconductor device B3 is smaller than that in the semiconductor device B2. In the example shown in FIG. 19, however, the element-to-element inductance L1 is greater than the element-to-terminal inductance L2. Incidentally, providing the conductive substrate 23A with the plurality of connecting portions 233A results in forming openings 234A opposite from the recesses in the conductive substrate 23A (the first gap G1) with respect to the respective connecting portions 233A, as shown in FIG. 19. The opening 234A penetrates the conductive substrate 23A in the thickness direction z. In the example shown in FIG. 19, each recess in the conductive substrate 23A (each first gap G1) is longer in length in the first direction x than the length of each opening 234A in the first direction x.

As shown in FIG. 19, the semiconductor device B3 also differs from the semiconductor device B2 in that the conductive substrate 23B additionally includes a plurality of connecting portions 233B. Each connecting portion 233B electrically connects two mounting portions 231B adjacent in the second direction y. In the semiconductor device B3, two mounting portions 231B adjacent in the second direction y are electrically connected via the connecting portion 232B and a connecting portion 233B. With this structure, each conduction path R21 is a path via a connecting portion 233B rather than a path via the connecting portion 232B as shown in FIG. 19. As a result, each conduction path R21 in the semiconductor device B3 is shorter than those in the semiconductor device B2, so that the element-to-element inductance L3 in the semiconductor device B3 is smaller than that in the semiconductor device B2. In the example shown in FIG. 19, however, the element-to-element inductance L3 is greater than the element-to-terminal inductance L4. Incidentally, providing the conductive substrate 23B with the plurality of connecting portions 233B results in forming openings 234B opposite from the recesses in the conductive substrate 23B (the second gap G2) with respect to the respective connecting portions 233B, as shown in FIG. 19. The opening 234B penetrates the conductive substrate 23B in the thickness direction z. In the example shown in FIG. 19, each recess in the conductive substrate 23B (each second gap G2) is longer in length in the first direction x than the length of each opening 234B in the first direction x.

### Third Variation of Second Embodiment

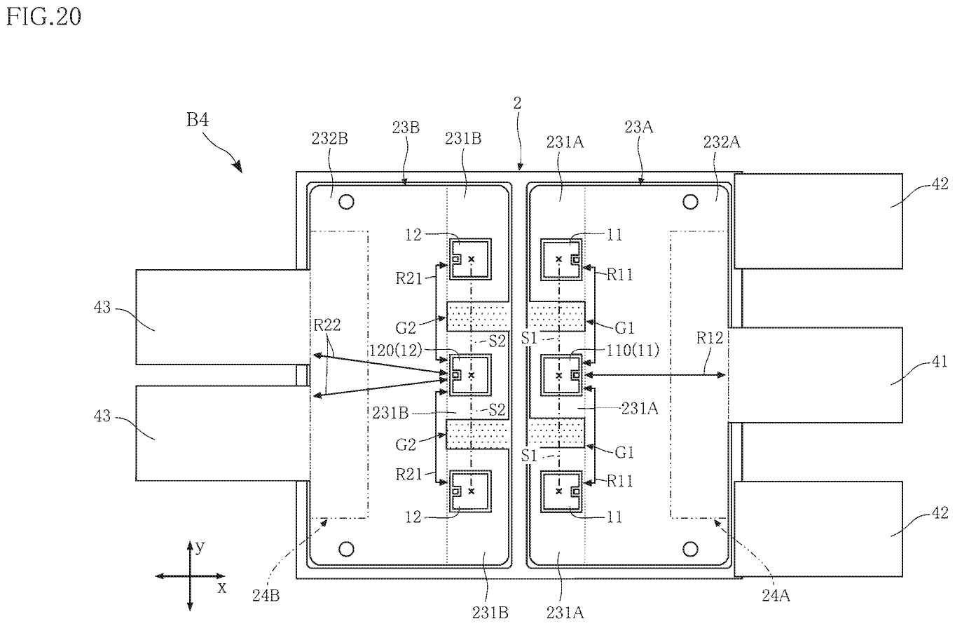

As shown in FIG. 20, each conduction path R11 in the semiconductor device B4 is shorter than those in the semiconductor device B2. That is, the element-to-element inductance L1 in the semiconductor device B4 is smaller than that in the semiconductor device B2. In the example shown in FIG. 20, each conduction path R11 is shorter, as a result that each recess formed in the conductive substrate 23A (i.e., each first gap G1) is shorter in length in the first direction x. In addition, the conduction path R12 in the semiconductor device B4 is longer than that in the semiconductor device B2. That is, the element-to-element inductance in L2 the semiconductor device B4 is smaller that than in the semiconductor device B2. In the example shown in FIG. 20, the conduction path R12 is longer, as a result that the first semiconductor elements 11 are located farther from the power terminal 41 in the first direction x than the first semiconductor elements 11 in the semiconductor device B2. In the semiconductor device B4, each conduction path R11 is longer than the conduction path R12. That is, in semiconductor device B4, the element-to-element inductance L1 is smaller than the element-to-terminal inductance L2.

As shown in FIG. 20, in addition, each conduction path R21 in the semiconductor device B4 is shorter than those in the semiconductor device B2. That is, the element-to-element inductance L3 in the semiconductor device B4 is smaller than that in the semiconductor device B2. In the example shown in FIG. 20, each conduction path R21 is shorter, as a result that each recess formed in the conductive substrate 23B (i.e., each second gap G2) is shorter in length in the first direction x. In addition, the conduction path R22 in the semiconductor device B4 is longer than that in the semiconductor device B2. That is, the element-to-element inductance L4 in the semiconductor device B4 is smaller than that in the semiconductor device B2. In the example shown in FIG. 20, the conduction path R22 is longer, as a result that the second semiconductor elements 12 are located farther from each power terminal 43 direction X than the second in the first semiconductor elements 12 in the semiconductor device B2. In the semiconductor device B4, each conduction path R21 is longer than the conduction path R22. That is, in semiconductor device B4, the element-to-element inductance L3 is smaller than the element-to-terminal inductance L4.

### Fourth Variation of Second Embodiment

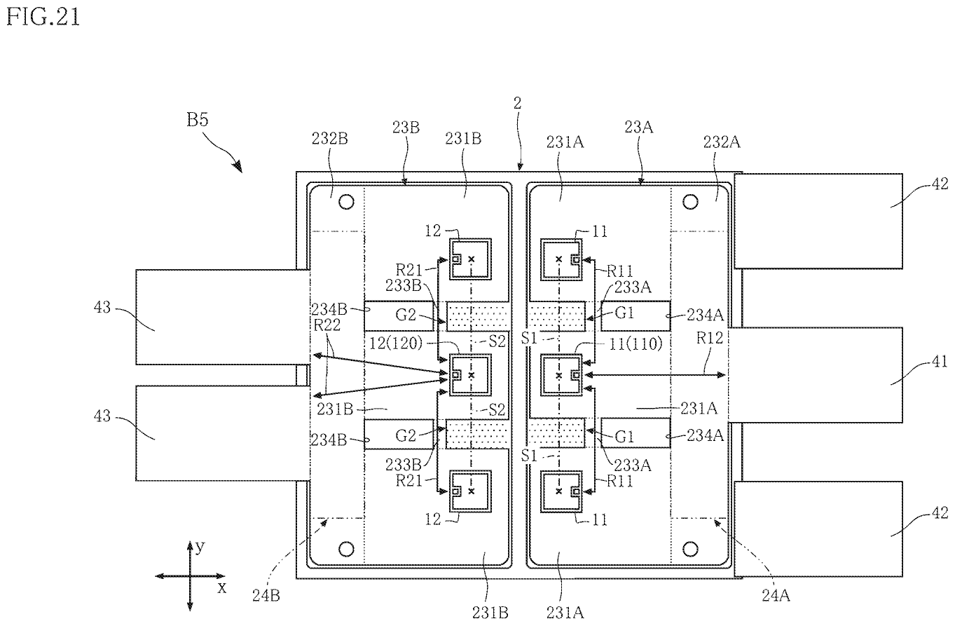

As shown in FIG. 21, the semiconductor device B5 is similar to the semiconductor device B3 in that the conductive substrate 23A additionally includes a plurality of connecting portions 233A. In the example shown in FIG. 21, each recess in the conductive substrate 23A (each first gap G1) is shorter in length in the first direction x than the length of each opening 234A in the first direction x. Similarly to the semiconductor device B4, in the semiconductor device B5, each conduction path R11 is shorter than the conduction path R12. That is, in semiconductor device B5, the element-to-element inductance L1 is smaller than the element-to-terminal inductance L2.

As shown in FIG. 21, the semiconductor device B5 is also similar to the semiconductor device B3 in that the conductive substrate 23B additionally includes a plurality of connecting portions 233B. In the example shown in FIG. 21, each recess in the conductive substrate 23B (each second gap G2) is shorter in length in the first direction x than the length of each opening 234B in the first direction x. Similarly to the semiconductor device B4, each conduction path R21 in the semiconductor device B5 is shorter than the conduction path R22. That is, in semiconductor device B5, the element-to-element inductance L3 is smaller than the element-to-terminal inductance L4.

The semiconductor devices B1 to B5 are examples in which each first gap G1 is provided by forming a recess in the conductive substrate 23A. In a different configuration, each first gap G1 may be provided by forming a through-hole in the conductive substrate 23A as in the example shown in FIG. 11. The through-hole penetrates the conductive substrate 23A in the thickness direction z. Similarly, the semiconductor devices B1 to B5 are examples in which each second gap G2 is provided by forming a recess in the conductive substrate 23B. In a different configuration, each second gap G2 may be provided by forming a through-hole in the conductive substrate 23B as in the example shown in FIG. 11. The through-hole penetrates the conductive substrate 23B in the thickness direction z.

### Third Embodiment

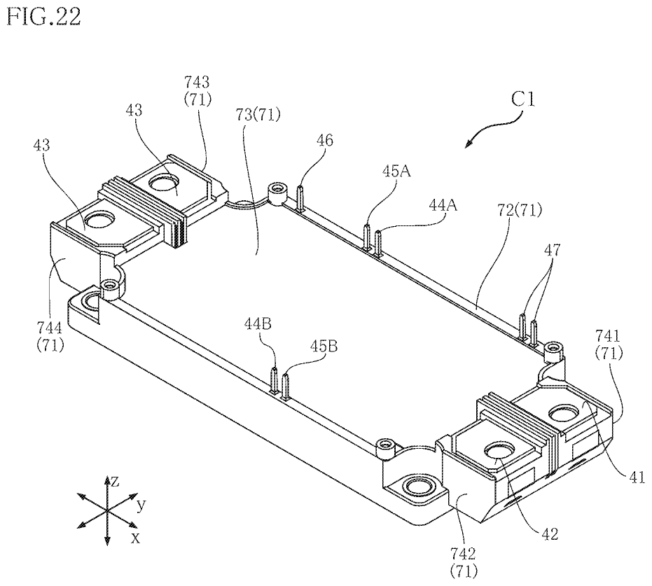

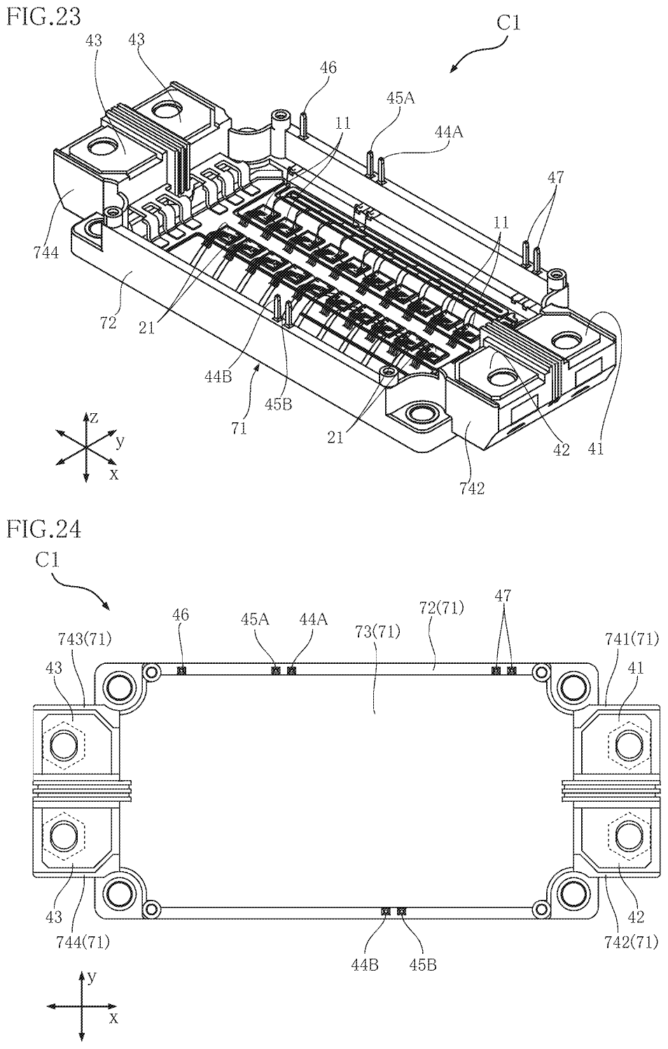

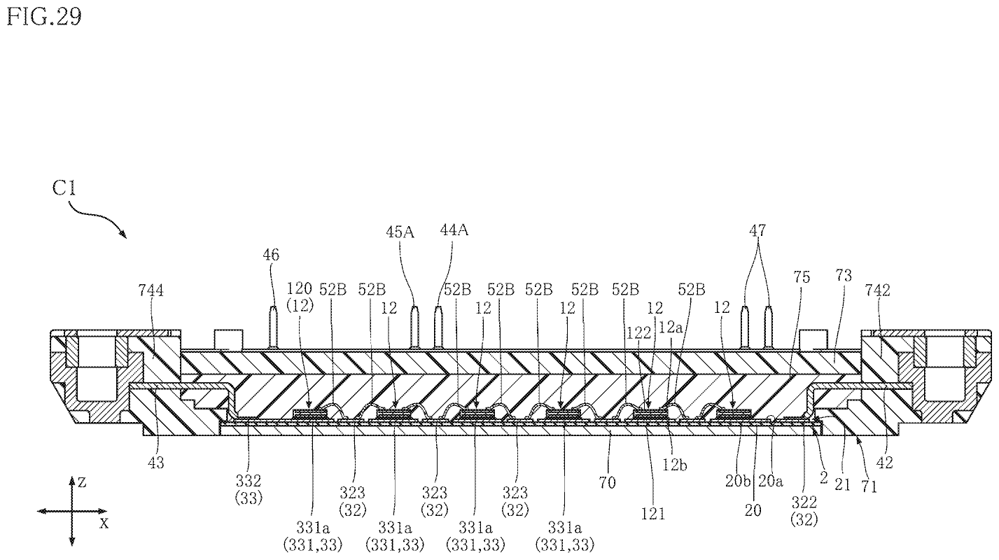

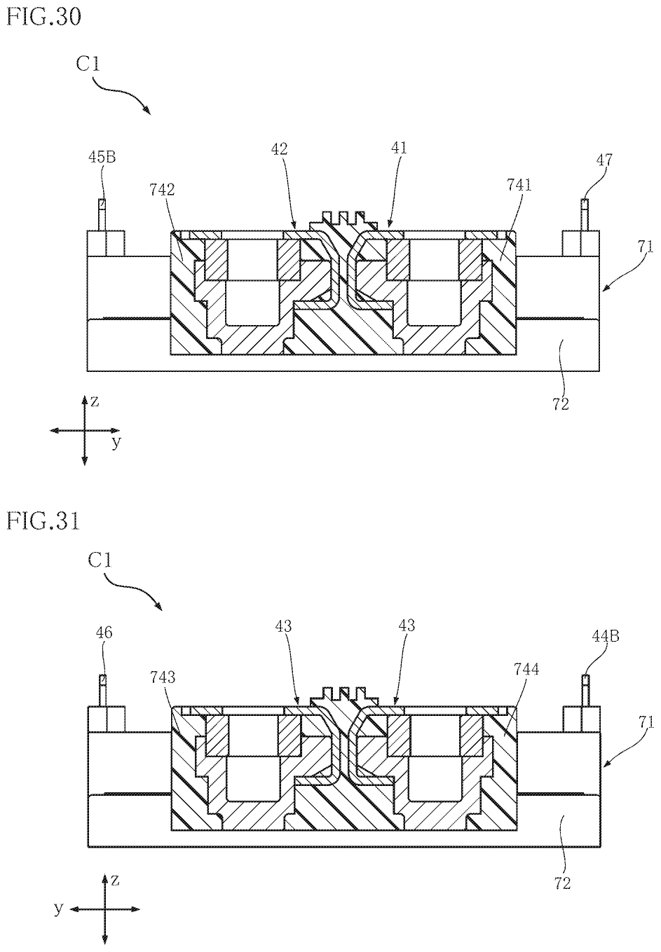

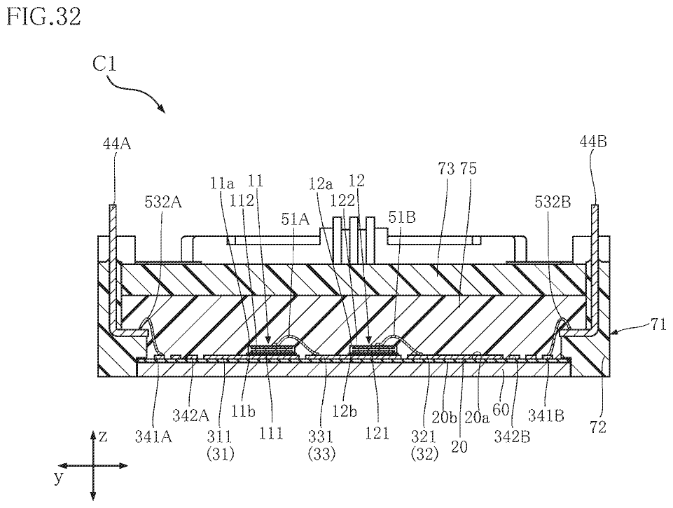

FIGS. 22 to 32 show a semiconductor device C1 according to a third embodiment. As shown in those figures, the semiconductor device C1 includes a plurality of first semiconductor elements 11, a plurality of second semiconductor elements 12, a supporting substrate 2, a plurality of terminals, a plurality of connecting members, a heat-dissipating plate 70, a case 71, and a resin member 75. The plurality of terminals include a plurality of power terminals 41 to 43 and a plurality of signal terminals 44A, 44B, 45A, 45B, 46, and 47. The plurality of connecting members include a plurality of connecting members 51A, 51B, 52A, 52B, 531A, 531B, 532A, 541A, 541B, 542A, 542B, 56, and 57.

In the first embodiment and the second embodiment, the first semiconductor elements 11 and the second semiconductor elements 12 are covered with the sealing member 6 to form a module. In the semiconductor device C1, in contrast, the first semiconductor elements 11 and the second semiconductor elements 12 are contained in the case 71 to form a module.

As can be seen from FIGS. 22 to 25 and 28 to 32, the case 71 has the shape of a rectangular parallelepiped, for example. The case 71 is made of a synthetic resin that is electrically insulating and heat-resistant, highly such as polyphenylenesulfide (PPS). In plan view, the case 71 has a rectangular shape that is roughly as large as the heat-dissipating plate 70. The case 71 includes a frame 72, a top plate 73, and a plurality of terminal bases 741 to 744.

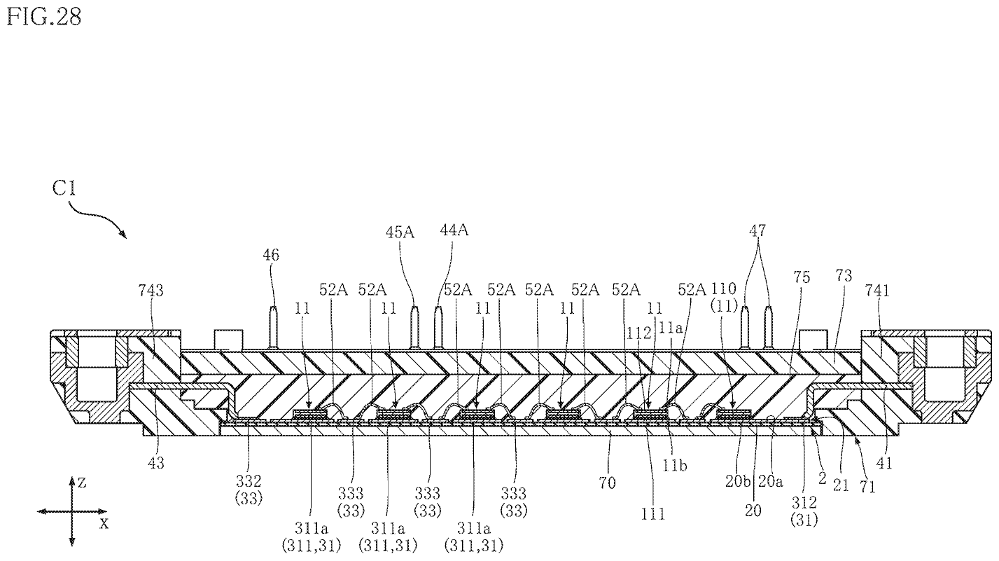

The frame 72 is fixed to the upper surface of the heat-dissipating plate 70 in the thickness direction z. The top plate 73 is fixed to the frame 72. As shown in FIGS. 22, 24, 28, 29, and 32, the top plate 73 closes the opening of the frame 72 at the upper end in the thickness direction z. As shown in FIGS. 28, 29, and 32, the top plate 73 faces the heat-dissipating plate 70 that closes the frame 72 at the lower end in the thickness direction z. The top plate 73, the heat-dissipating plate 70, and the frame 72 together form a circuit housing space (a space for storing the first semiconductor elements 11 and the second semiconductor elements 12) inside the case 71. In the following description, the circuit housing space may be referred to as the inside of the case 71.

The two terminal bases 741 and 742 are located in the first sense of the first direction x from the frame 72 and integral formed with the frame 72. The two terminal bases 743 and 744 are located in the second sense of the first direction x from the frame 72 and integrally formed with the frame 72. The two terminal bases 741 and 742 are aligned in the second direction y along the side wall of the frame 72 located in the first sense of the first direction x. The terminal base 741 covers a portion of the power terminal 41, and a portion of the power terminal 41 is located on the upper surface of the terminal base 741 in the thickness direction z as shown in FIG. 22. The terminal base 742 covers a portion of the power terminal 42, and a portion of the power terminal 42 is located on the upper surface of the terminal base 742 in the thickness direction z as shown in FIG. 22. The two terminal bases 743 and 744 are aligned in the second direction y along the side wall of the frame 72 located in the second sense of the first direction x. The terminal base 743 covers a portion of one of the two power terminals 43, and a portion of that power terminal 43 is located on the upper surface of the terminal base 743 in the thickness direction z as shown in FIG. 22. The terminal base 744 covers a portion of the other power terminal 43, and a portion of that power terminal 43 is located on the upper surface of the terminal base 744 in the thickness direction z as shown in FIG. 22.

The resin member 75 fills the space (the circuit hosing space described above) enclosed by the top plate 73, the heat-dissipating plate 70, and the frame 72 as shown in FIGS. 28, 29 and 32. The resin member 75 covers the first semiconductor elements 11, the second semiconductor elements 12, and so on. The resin member 75 is made of a black epoxy resin, for example. Alternatively to the epoxy resin, the resin member 75 may be made of other insulating materials, including silicone gel. The semiconductor device C1 is not limited to this configuration, and the resin member 75 may be omitted. In addition, the top plate 73 of the case 71 may be omitted when the resin member 75 is included.

The supporting substrate 2 of the semiconductor device C1 is bonded to the heat-dissipating plate 70. The supporting substrate 2 of the semiconductor device C1 includes an insulating substrate 20 and an obverse-surface metal layer 21. In a different configuration, the supporting substrate 2 may include a reverse-surface metal layer 22.

The obverse-surface metal layer 21 includes the power wiring sections 31 to 33 and the signal wiring sections 34A, 34B, 35A, 35B, and 37. Unlike the obverse-surface metal layer 21 of the semiconductor device A1, the obverse-surface metal layer 21 of the semiconductor device C1 additionally includes the pair of signal wiring sections 37.

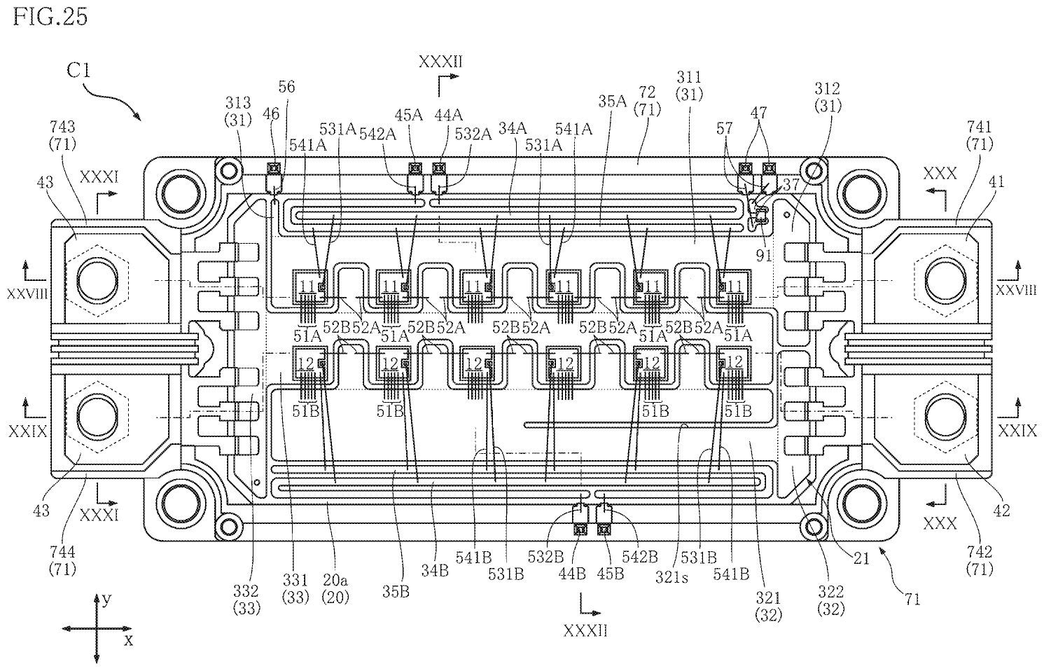

As shown in FIG. 25, the signal wiring sections 37 are spaced apart in the second direction y. To the signal wiring sections 37, a thermistor 91 may be bonded. The thermistor 91 spans from one of the signal wiring sections 37 to the other. In an example different from the semiconductor device C1, no thermistor 91 is bonded to the signal wiring sections 37. As shown in FIG. 25, the signal wiring sections 37 are located at a corner portion of the insulating substrate 20. The pair of signal wiring sections 37 are located between the pad portion 312 and the two signal wiring sections 34A and 35A in the first direction x.

The power wiring section 31 of the semiconductor device C1 includes two pad portions 311 and 312 similarly to the power wiring section 31 of the semiconductor device A1, and includes an extending portion 313 unlike the power wiring section 31 of the semiconductor device A1.

As shown in FIG. 25, the extending portion 313 extends in the second direction y from the end of the pad portion 311 in the second sense of the first direction x (the end remote from the power terminal 41). In the example shown in FIG. 25, the extending portion 313 is located between the pad portion 332 (the power wiring section 33) and the two signal wiring sections 34A and 35A in plan view.

The pad portion 321 of the power wiring section 32 has a slit 321s as shown in FIG. 25. The slit 321s extends in the first direction x, starting from the edge of the pad portion 321 in the first sense of the first direction x (the edge closer to the pad portion 322). The slit 321s ends at the central portion of the pad portion 321 in the first direction x.

As shown in FIG. 25, the connecting member 56 is bonded to the signal terminal 46. The signal terminal 47 is electrically connected to the power wiring section 31 via the connecting member 56. Consequently, the signal terminal 46 is electrically connected to the first electrode 111 (drain) of each first semiconductor element 11. The signal terminal 46 is for output terminal of a third detection signal. The third detection signal is a voltage signal corresponding to the current flowing through the power wiring section 31 (that is the drain current, which is the current flowing through the first electrode 111 (drain) of each first semiconductor element 11). While the signal terminal 46 in the semiconductor device B1 is a press-fit terminal, the signal terminal 46 in the semiconductor device C1 is a pin-like metal member just as the other signal terminals 44A, 44B, 45A, 45B, and so on.

As shown in FIG. 25, the pair of connecting members 57 are bonded to the pair of signal terminals 47. Each signal terminal 47 is electrically connected to one of the signal wiring sections 37 via the relevant connecting member 57. This electrically connects the pair of signal terminals 47 to the thermistor 91. The pair of signal terminals 47 are terminals used for detecting the case 71. In the example without the thermistor 91 connected to the pair of signal wiring sections 37, the pair of signal terminals 47 are non-connect terminals.

As shown in FIG. 25, the connecting member 532A is bonded to the signal wiring section 34A and the signal terminal 44A to provide electrical connection between them. In the semiconductor device C1, the signal terminal 44A is thus electrically connected to the third electrodes 113 (gates) of the first semiconductor elements 11 via the connecting member 532A, the signal wiring section 34A, and the connecting members 531A.

As shown in FIG. 25, the connecting member 532B is bonded to the signal wiring section 34B and the signal terminal 44B to provide electrical connection between them. In the semiconductor device C1, the signal terminal 44B is thus electrically connected to the sixth electrodes 123 (gates) of the second semiconductor elements 12 via the connecting member 532B, the signal wiring section 34B, and the connecting members 531B.

As shown in FIG. 25, the connecting member 542A is bonded to the signal wiring section 35A and the signal terminal 45A to provide electrical connection between them. In the semiconductor device C1, the signal terminal 45A is thus electrically connected to the second electrodes 112 (sources) of the first semiconductor elements 11 via the connecting member 542A, the signal wiring section 35A, and the connecting members 541A.

As shown in FIG. 25, the connecting member 542B is bonded to the signal wiring section 35B and the signal terminal 45B to provide electrical connection between them. In the semiconductor device C1, the signal terminal 45B is thus electrically connected to the fifth electrodes 122 (sources) of the second semiconductor elements 12 via the connecting member 542B, the signal wiring section 35B, and the connecting members 541B.

As shown in FIG. 25, the connecting member 56 is bonded to the extending portion 313 and the signal terminal 47 to electrically connect the power wiring section 31 and the signal terminal 47. Consequently, the signal terminal 47 is electrically connected to the first electrodes 111 (drains) of the first semiconductor elements 11 via the connecting member 56 and the power wiring section 31.

As shown in FIG. 25, each connecting member 57 is bonded to one of the signal wiring sections 37 and one of the signal terminals 47 to provide electrical connection between them. Consequently, the pair of signal terminals 47 are electrically connected to the thermistor 91 via the pair of connecting members 57 and the pair of signal wiring sections 37. In the example in which no thermistor 91 is connected to the pair of signal wiring sections 37, the pair of connecting members 57 are not necessary.

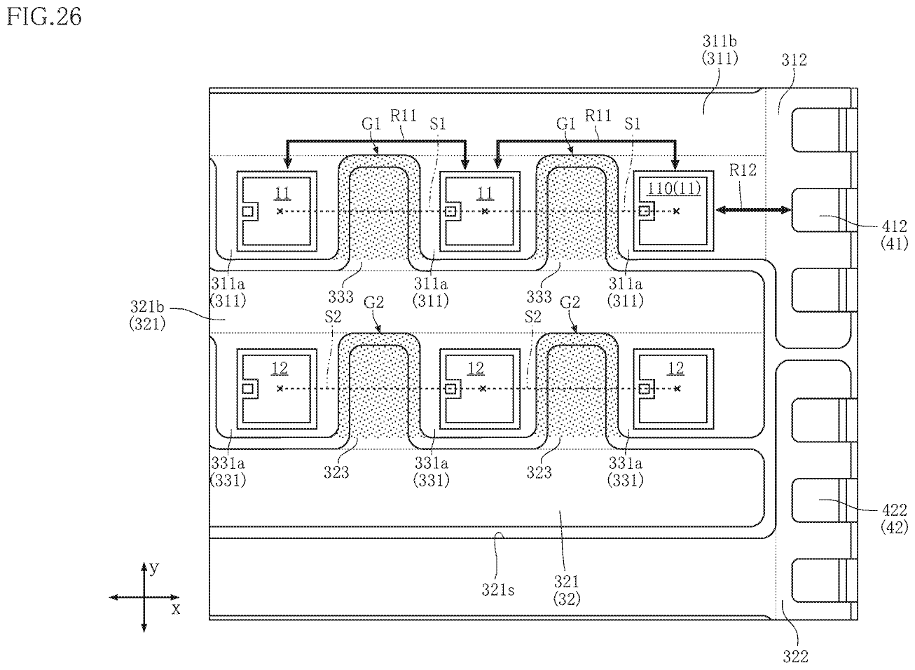

In the semiconductor device C1, each conduction path R11 between the first electrodes 111 (drains) of two first semiconductor elements 11 adjacent in the first direction x (see FIG. 26) is longer than the conduction path R12 between the first electrode 111 (drain) of the first proximity element 110 and the power terminal 41 (P terminal) (see FIG. 26). Consequently, the element-to-element inductance L1, which is the inductance of the conduction path R11, is greater than the element-to-terminal inductance L2, which is the inductance of the conduction path R12.

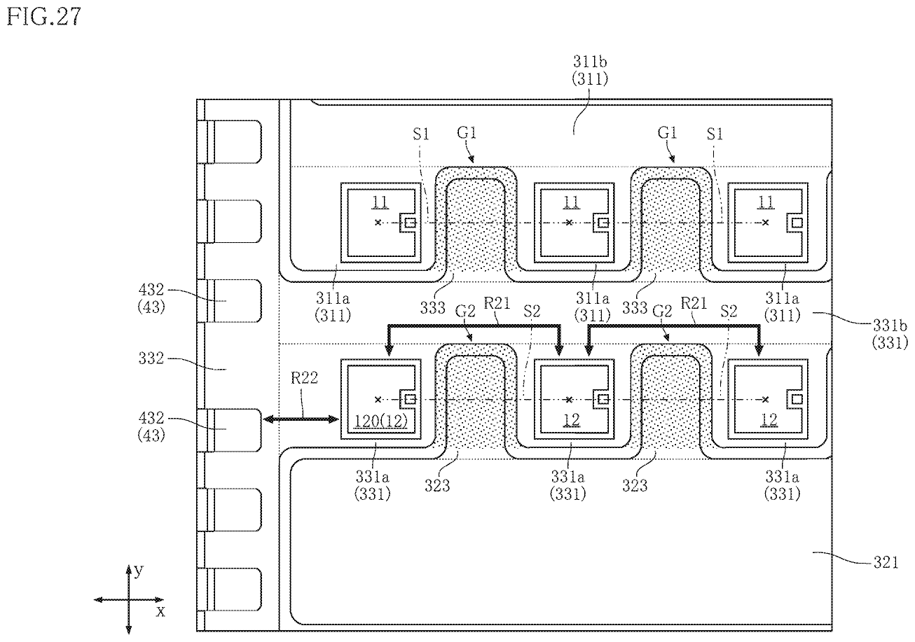

In the semiconductor device C1, each conduction path R21 between the fourth electrodes 121 (drains) of two second semiconductor elements 12 adjacent in the first direction x (see FIG. 27) is longer than the conduction path R22 between the fourth electrode 121 (drain) of the second proximity element 120 and each power terminal 43 (OUT terminal) (see FIG. 27). Consequently, the element-to-element inductance L3, which is the inductance of the conduction path R21, is greater than the element-to-terminal inductance L4, which is the inductance of the conduction path R22.

The operation and effect of the semiconductor device C1 are as follows.

Similarly to the semiconductor device A1, the semiconductor device C1 includes the plurality of first semiconductor elements 11, and those first semiconductor elements 11 are electrically connected in parallel. The semiconductor device C1 includes the mounting portion 311a as a first conductor. The mounting portion 311a is disposed to avoid being located on a portion of each first line segment S1 as viewed in the thickness direction z. Similarly to the semiconductor device A1, the semiconductor device C1 can therefore suppress the oscillation phenomenon during the parallel operation of the first semiconductor elements 11 more efficiently than the first comparative configuration described above.

Similarly to semiconductor device A1, the semiconductor device C1 includes the plurality of second semiconductor elements 12, and those second semiconductor elements 12 are electrically connected in parallel. The semiconductor device C1 includes the mounting portion 331a as a second conductor. The mounting portion 331a is disposed to avoid being located on a portion of each second line segment S2 as viewed in the thickness direction z. Similarly to the semiconductor device A1, the semiconductor device C1 can therefore suppress the oscillation phenomenon during the parallel operation of the second semiconductor elements 12 more efficiently than the second comparative configuration described above.

In addition, the semiconductor device C1 has one or more features in common with one or more of the semiconductor devices A1 to A5 and B1 to B5, thereby achieving similar effects as those achieved by the semiconductor devices A1 to A5 and B1 to B5. The semiconductor device C1 may be modified to include any of the features of the semiconductor devices A2 to A5 and B2 to B5.

In addition, although semiconductor devices the according to the first to third embodiments include the plurality of first semiconductor elements 11 and the plurality of second semiconductor elements 12, the present disclosure is not limited to such and the second semiconductor elements 12 may be omitted.

The semiconductor devices according to the present disclosure are not limited to the embodiments described above. The specific configuration of each part of a semiconductor device according to the present disclosure may suitably be designed and changed in various manners. The present disclosure includes the embodiments described in the following clauses.

### Clause 1.

A semiconductor device comprising:
two first semiconductor elements each including a first electrode, a second electrode, and a third electrode and each controlled to switch between an on-state and an off-state by a first drive signal inputted to the third electrode;
a first conductor electrically interposed between the first electrodes of the two first semiconductor elements; and
a first power terminal electrically connected to the first conductor and electrically conducting to the first electrodes of the two first semiconductor elements,
wherein the two first semiconductor elements are electrically connected in parallel, and
the first conductor is disposed to avoid being located on a portion of a first line segment connecting centers of the two first semiconductor elements as viewed in a thickness direction of the first conductor.

### Clause 2.

The semiconductor device according to Clause 1, wherein the first conductor is disposed to avoid being located on at least 15% and at most 90% of the first line segment as viewed in the thickness direction.

### Clause 3.

The semiconductor device according to Clause 1 or 2, wherein the first conductor includes two first mounting portions on which the two first semiconductor elements are mounted,
the two first mounting portions are disposed with a first gap interposed therebetween in a first direction orthogonal to the thickness direction, and
the first gap intersects the first line segment as viewed in the thickness direction.

### Clause 4.

The semiconductor device according to Clause 3, wherein the first conductor includes a first connecting portion connected to both of the two first mounting portions, and
the first connecting portion is located in a first sense of a second direction orthogonal to the thickness direction and the first direction from the first line segment.

### Clause 5.

The semiconductor device according to Clause 4, wherein the first conductor includes a pad portion to which the first power terminal is bonded,
the first power terminal is located farther in a first sense of the first direction than the two first semiconductor elements, and
the first connecting portion extends from the pad portion in a second sense of the first direction as viewed in the thickness direction.

### Clause 6.

The semiconductor device according to Clause 5, wherein each of the two first semiconductor elements includes a first-element obverse surface and a first-element reverse surface spaced apart in the thickness direction,
the first electrode is disposed on the first-element reverse surface,
the second electrode and the third electrode are disposed on the first-element obverse surface, and
each of the two first semiconductor elements is disposed with the first-element reverse surface facing the first conductor.

### Clause 7.

The semiconductor device according to Clause 6, further comprising:
a second conductor spaced apart from the first conductor;
two first connecting members electrically connecting the second conductor and the second electrode of each of the two first semiconductor elements; and
a second power terminal electrically connected to the second conductor and electrically conducting to the second electrodes of the two first semiconductor elements.

### Clause 8.

The semiconductor device according to Clause 7, wherein the second conductor is located on a same side as the two first mounting portions in the second direction with respect to the first connecting portion.

### Clause 9.

The semiconductor device according to Clause 8, wherein the second conductor includes a projecting portion protruding in the second direction as viewed in the thickness direction and overlapping in part with the first gap as viewed in the thickness direction.

### Clause 10.

The semiconductor device according to Clause 8 or 9, further comprising two second semiconductor elements each including a fourth electrode, a fifth electrode, and a sixth electrode and each controlled to switch between an on-state and an off-state by a second drive signal inputted to the sixth electrode,
wherein the two second semiconductor elements are electrically connected in parallel,
the second conductor is electrically interposed between the fourth electrodes of the two second semiconductor elements, and
the second power terminal is electrically conducting to the fourth electrodes of the two second semiconductor elements.

### Clause 11.

The semiconductor device according to Clause 10, wherein the second conductor is disposed to avoid being located on a portion of a second line segment connecting centers of the two second semiconductor elements as viewed in the thickness direction.

### Clause 12.

The semiconductor device according to Clause 11, wherein the second conductor is disposed to avoid being located on at least 15% and at most 90% of the second line segment as viewed in the thickness direction.

### Clause 13.

The semiconductor device according to Clause 11 or 12, wherein the second conductor includes two second mounting portions on which the two second semiconductor elements are mounted,
the two second mounting portions are disposed with a second gap interposed therebetween in the first direction, and
the second gap intersects the second line segment as viewed in the thickness direction.

### Clause 14.

The semiconductor device according to Clause 13, wherein the second conductor includes a second connecting portion connected to both of the two second mounting portions,
the second connecting portion is located in the first sense of the second direction from the second line segment, and
the two first connecting members are each connected to the second connecting portion.

### Clause 15.

The semiconductor device according to Clause 14, wherein each of the two second semiconductor elements includes a second-element obverse surface and a second-element reverse surface spaced apart in the thickness direction,
the fourth electrode is disposed on the second-element reverse surface,
the fifth electrode and the sixth electrode are disposed on the second-element obverse surface, and
each of the two second semiconductor elements is disposed with the second-element reverse surface facing the second conductor.

### Clause 16.

The semiconductor device according to Clause 15, further comprising:
a third conductor spaced apart from the first conductor and the second conductor;
two second connecting members electrically connecting the third conductor and the fifth electrode of each of the two second semiconductor elements; and
a third power terminal electrically connected to the third conductor and electrically conducting to the fifth electrodes of the two second semiconductor elements.

### Clause 17.

The semiconductor device according to Clause 16, wherein the first power terminal and the third power terminal are input terminals for a direct-current power,
the direct-current power is converted to an alternating-current power by the two first semiconductor elements and the two second semiconductor elements each switching between the on-state and the off-state, and
the second power terminal is an output terminal for the alternating-current power.

### Clause 18.

The semiconductor device according to Clause 17, further comprising an insulating substrate supporting the first conductor, the second conductor, and the third conductor.

REFERENCE NUMERALS

A1 to A5, B1 to B5, C1: Semiconductor device
11: First semiconductor element
11a: first-element obverse surface
11b: First-element reverse surface
110: First proximity element
111: First electrode
112: Second electrode
113: Third electrode
12: Second semiconductor element
12a: Second-element obverse surface
12b: Second-element reverse surface
120: Second proximity element
121: Fourth electrode
122: Fifth electrode
123: Sixth electrode
2: Supporting substrate
20: Insulating substrate
20a: Obverse surface
20b: Reverse surface
21, 21A, 21B: Obverse-surface metal layer
22: Reverse-surface metal layer
23A, 23B: Conductive substrate
231A, 231B: Mounting portion
232A, 232B: Connecting portion
233A, 233B: Connecting portion
234A, 234B: Opening
24A, 24B: Signal substrate
241: Insulating layer
241a: Obverse surface
241b: Reverse surface
242: Obverse-surface metal layer
243: Reverse-surface metal layer
31, 32, 33: Power wiring section
311, 321, 331: Pad portion
311a, 331a: Mounting portion
311b, 331b: Connecting portion
311c, 331c: Connecting portion
311d, 331d: Strip-shaped portion
311e, 331e: Through-hole
321s: Slit
312, 322, 332: Pad portion
313: Extending portion
323, 333: Projecting portion
34A, 34B, 35A, 35B, 36, 37, 39: Signal wiring section
41, 42, 43: Power terminal
411, 421, 431: Bonding portion
412, 422, 432: Terminal portion
44A, 44B, 45A, 45B, 46, 47, 49: Signal terminal
441: Holder
442: Metal pin
51A, 51B, 52A, 52B, 56, 57: Connecting member
531A, 531B, 532A, 532B: Connecting member
541A, 541B, 542A, 542B: Connecting member
58A, 58B: Connecting member
581B: First wiring section
582B: Second wiring section
583B: Third wiring section
584B: Fourth wiring section
6: Sealing member
61: Resin obverse surface
62: Resin reverse surface
631 to 634: Resin side surface
70: Heat-dissipating plate
71: Case
72: Frame
73: Top plate
741 to 743: Terminal base
75: Resin member
91: Thermistor

1. A semiconductor device comprising:
two first semiconductor elements each including a first electrode, a second electrode, and a third electrode and each controlled to switch between an on-state and an off-state by a first drive signal inputted to the third electrode;
a first conductor electrically interposed between the first electrodes of the two first semiconductor elements; and
a first power terminal electrically connected to the first conductor and electrically conducting to the first electrodes of the two first semiconductor elements,
wherein the two first semiconductor elements are electrically connected in parallel, and
the first conductor is disposed to avoid being located on a portion of a first line segment connecting centers of the two first semiconductor elements as viewed in a thickness direction of the first conductor.

2. The semiconductor device according to claim 1, wherein the first conductor is disposed to avoid being located on at least 15% and at most 90% of the first line segment as viewed in the thickness direction.

3. The semiconductor device according to claim 1, wherein the first conductor includes two first mounting portions on which the two first semiconductor elements are mounted,
the two first mounting portions are disposed with a first gap interposed therebetween in a first direction orthogonal to the thickness direction, and
the first gap intersects the first line segment as viewed in the thickness direction.

4. The semiconductor device according to claim 3, wherein the first conductor includes a first connecting portion connected to both of the two first mounting portions, and
the first connecting portion is located in a first sense of a second direction orthogonal to the thickness direction and the first direction from the first line segment.

5. The semiconductor device according to claim 4, wherein the first conductor includes a pad portion to which the first power terminal is bonded,
the first power terminal is located farther in a first sense of the first direction than the two first semiconductor elements, and
the first connecting portion extends from the pad portion in a second sense of the first direction as viewed in the thickness direction.

6. The semiconductor device according to claim 5, wherein each of the two first semiconductor elements includes a first-element obverse surface and a first-element reverse surface spaced apart in the thickness direction,
the first electrode is disposed on the first-element reverse surface,
the second electrode and the third electrode are disposed on the first-element obverse surface, and
each of the two first semiconductor elements is disposed with the first-element reverse surface facing the first conductor.

7. The semiconductor device according to claim 6, further comprising:
a second conductor spaced apart from the first conductor;
two first connecting members electrically connecting the second conductor and the second electrode of each of the two first semiconductor elements; and
a second power terminal electrically connected to the second conductor and electrically conducting to the second electrodes of the two first semiconductor elements.

8. The semiconductor device according to claim 7, wherein the second conductor is located on a same side as the two first mounting portions in the second direction with respect to the first connecting portion.

9. The semiconductor device according to claim 8, wherein the second conductor includes a projecting portion protruding in the second direction as viewed in the thickness direction and overlapping in part with the first gap as viewed in the thickness direction.

10. The semiconductor device according to claim 8, further comprising two second semiconductor elements each including a fourth electrode, a fifth electrode, and a sixth electrode and each controlled to switch between an on-state and an off-state by a second drive signal inputted to the sixth electrode,
wherein the two second semiconductor elements are electrically connected in parallel,
the second conductor is electrically interposed between the fourth electrodes of the two second semiconductor elements, and
the second power terminal is electrically conducting to the fourth electrodes of the two second semiconductor elements.

11. The semiconductor device according to claim 10, wherein the second conductor is disposed to avoid being located on a portion of a second line segment connecting centers of the two second semiconductor elements as viewed in the thickness direction.

12. The semiconductor device according to claim 11, wherein the second conductor is disposed to avoid being located on at least 15% and at most 90% of the second line segment as viewed in the thickness direction.

13. The semiconductor device according to claim 11, wherein the second conductor includes two second mounting portions on which the two second semiconductor elements are mounted,
the two second mounting portions are disposed with a second gap interposed therebetween in the first direction, and
the second gap intersects the second line segment as viewed in the thickness direction.

14. The semiconductor device according to claim 13, wherein the second conductor includes a second connecting portion connected to both of the two second mounting portions,
the second connecting portion is located in the first sense of the second direction from the second line segment, and
the two first connecting members are each connected to the second connecting portion.

15. The semiconductor device according to claim 14, wherein each of the two second semiconductor elements includes a second-element obverse surface and a second-element reverse surface spaced apart in the thickness direction,
the fourth electrode is disposed on the second-element reverse surface,
the fifth electrode and the sixth electrode are disposed on the second-element obverse surface, and
each of the two second semiconductor elements is disposed with the second-element reverse surface facing the second conductor.

16. The semiconductor device according to claim 15, further comprising:
a third conductor spaced apart from the first conductor and the second conductor;
two second connecting members electrically connecting the third conductor and the fifth electrode of each of the two second semiconductor elements; and
a third power terminal electrically connected to the third conductor and electrically conducting to the fifth electrodes of the two second semiconductor elements.

17. The semiconductor device according to claim 16, wherein the first power terminal and the third power terminal are input terminals for a direct-current power,
the direct-current power is converted to an alternating-current power by the two first semiconductor elements and the two second semiconductor elements each switching between the on-state and the off-state, and
the second power terminal is an output terminal for the alternating-current power.

18. The semiconductor device according to claim 17, further comprising an insulating substrate supporting the first conductor, the second conductor, and the third conductor.
